(19) United States
(12) Patent Application Publication
(10) Pub. No.: US 2025/0185406 A1
(43) Pub. Date: Jun. 5, 2025

(54) SEMICONDUCTOR DEVICE AND ELECTRONIC DEVICE

(71) Applicant: SONY SEMICONDUCTOR SOLUTIONS CORPORATION, KANAGAWA (JP)

(72) Inventor: YASUO KANDA, KANAGAWA (JP)

(21) Appl. No.: 18/844,024

(22) PCT Filed: Feb. 20, 2023
(86) PCT No.: PCT/JP2023/005900

§ 371 Date: Sep. 4, 2024

(30) Foreign Application Priority Data
Mar. 11, 2022 (JP) 2022-038349

(51) Int. Cl. H10F 39/95; H01L 23/00; H01L 25/16; H10B 61/00; H10B 80/00

(52) U.S. Cl. CPC H10F 39/95; H01L 25/167; H10B 61/00; H10B 80/00; H01L 24/08; H01L 2224/08145

(57) ABSTRACT

Provided is a semiconductor device (10) including a stack of a first semiconductor substrate (100) and a second semiconductor substrate (200), in which the first semiconductor substrate includes an imaging element (300) that generates a charge in response to light from a light incident surface of the first semiconductor substrate and a first memory element (400) provided on a side opposite to the light incident surface with respect to the imaging element, and the first memory element has a stacked structure in which a magnetization fixed layer (402), a nonmagnetic layer (404), and a storage layer (406) are stacked in the order mentioned from the light incident surface side.

### FIELD

The present disclosure relates to a semiconductor device and an electronic device.

### BACKGROUND

In recent years, for the purpose of miniaturization and others, imaging devices have a three-dimensional structure including two semiconductor substrates bonded to each other, and a circuit including an imaging element, a storage element (memory element), a plurality of transistors, and others is provided on these semiconductor substrates.

### CITATION LIST

### Patent Literature

Patent Literature 1: JP 2014-220376 A

### SUMMARY

### Technical Problem

However, in a semiconductor device (imaging device) having a three-dimensional structure, it is difficult to form a storage element (memory element) having a small cell size, a small circuit scale, and the like and having favorable characteristics.

Therefore, the present disclosure proposes a semiconductor device and an electronic device capable of easily forming a semiconductor device having a three-dimensional structure, the semiconductor device having a storage element having a small cell size, a small circuit scale, and the like and having favorable characteristics.

### Solution to Problem

According to the present disclosure, there is provided a semiconductor device including a stack of a first semiconductor substrate and a second semiconductor substrate. In the semiconductor device, the first semiconductor substrate includes: an imaging element that generates a charge in response to light from a light incident surface of the first semiconductor substrate; and a first memory element provided on a side opposite to the light incident surface with respect to the imaging element, and the first memory element has a stacked structure in which a magnetization fixed layer, a nonmagnetic layer, and a storage layer are stacked in the order mentioned from the light incident surface side.

Furthermore, according to the present disclosure, there is provided an electronic device mounted with a semiconductor device. The semiconductor device includes a stack of a first semiconductor substrate and a second semiconductor substrate. In the semiconductor device, the first semiconductor substrate includes: an imaging element that generates a charge in response to light from a light incident surface of the first semiconductor substrate; and a first memory element provided on a side opposite to the light incident surface with respect to the imaging element, and the first memory element has a stacked structure in which a magnetization fixed layer, a nonmagnetic layer, and a storage layer are stacked in the order mentioned from the light incident surface side.

### BRIEF DESCRIPTION OF DRAWINGS

FIG. 1 is an explanatory diagram schematically illustrating a stacked structure of an imaging device 10a according to a comparative example.

FIG. 2 is an explanatory diagram schematically illustrating a stacked structure of an MIJ element 400a according to a comparative example.

FIG. 3 is an explanatory diagram schematically illustrating a circuit configuration of the MIJ element 400a according to the comparative example.

FIG. 4 is an explanatory diagram (part 1) for explaining the background having led to elaboration of an embodiment of the present disclosure.

FIG. 5 is an explanatory diagram (part 2) for explaining the background having led to elaboration of the embodiment of the present disclosure.

FIG. 6 is an explanatory diagram (part 3) for explaining the background having led to elaboration of the embodiment of the present disclosure.

FIG. 7 is an explanatory diagram (part 4) for explaining the background having led to elaboration of the embodiment of the present disclosure.

FIG. 8 is an explanatory diagram schematically illustrating a stacked structure of an imaging device 10 according to an embodiment of the present disclosure.

FIG. 9 is an explanatory diagram schematically illustrating a stacked structure of an MIJ element 400 according to an embodiment of the present disclosure.

FIG. 10A is a cross-sectional view (part 1) in one step of a manufacturing method of the MIJ element 400 according to the embodiment of the present disclosure.

FIG. 10B is a cross-sectional view (part 2) in one step of the manufacturing method of the MTJ element 400 according to the embodiment of the present disclosure.

FIG. 10C is a cross-sectional view (part 3) in one step of the manufacturing method of the MTJ element 400 according to the embodiment of the present disclosure.

FIG. 10D is a cross-sectional view (part 4) in one step of the manufacturing method of the MIJ element 400 according to the embodiment of the present disclosure.

FIG. 11 is a cross-sectional view in one step of the manufacturing method of the imaging device 10 according to the embodiment of the present disclosure.

FIG. 12 is an explanatory diagram illustrating a modification of a memory area according to the embodiment of the present disclosure.

FIG. 13 is an explanatory diagram illustrating an example of a circuit of a memory area according to an embodiment of the present disclosure.

FIG. 14 is an explanatory diagram (part 1) illustrating a configuration of an imaging device 10 according to a modification of the embodiment of the present disclosure.

FIG. 15 is an explanatory diagram (part 2) illustrating the configuration of the imaging device 10 according to the modification of the embodiment of the present disclosure.

FIG. 16 is an explanatory diagram (part 1) illustrating a control example of the imaging device 10 according to the modification of the embodiment of the present disclosure.

FIG. 17 is an explanatory diagram (part 2) illustrating the control example of the imaging device 10 according to the modification of the embodiment of the present disclosure.

FIG. 18 is an explanatory diagram (part 3) illustrating the control example of the imaging device 10 according to the modification of the embodiment of the present disclosure.

FIG. 19 is an explanatory diagram (part 1) illustrating a circuit configuration example of an MIJ element 400 according to a modification of the embodiment of the present disclosure.

FIG. 20 is an explanatory diagram (part 2) illustrating a circuit configuration example of the MIJ element 400 according to the modification of the embodiment of the present disclosure.

FIG. 21 is an explanatory diagram illustrating an example of a schematic functional configuration of a camera.

FIG. 22 is a block diagram illustrating an example of a schematic functional configuration of a smartphone.

FIG. 23 is a block diagram illustrating a configuration example of a vehicle control system.

FIG. 24 is a diagram illustrating an example of sensing areas.

### DESCRIPTION OF EMBODIMENTS

Hereinafter, preferred embodiments of the present disclosure will be described in detail by referring to the accompanying drawings. Note that, in the present specification and the drawings, components having substantially the same functional configuration are denoted by the same symbols, and redundant description is omitted. Meanwhile, in the present specification and the drawings, a plurality of components having substantially the same or similar functional configurations may be distinguished by attaching different alphabets after the same symbol. However, in a case where it is not particularly necessary to distinguish each of the plurality of components having substantially the same or similar functional configurations, only the same symbol is attached.

In addition, the drawings referred to in the following description are drawings for describing and promoting understanding of an embodiment of the present disclosure, and shapes, dimensions, ratios, and the like illustrated in the drawings may be different from actual ones for the sake of facilitating understanding. Furthermore, an imaging device illustrated in the drawings can be modified in design as appropriate in consideration of the following description and known technology.

The description of specific lengths or shapes in the following description does not mean only the same values as mathematically defined numerical values or geometrically defined shapes. Specifically, the description of a specific length or shape in the following description includes a case where there is an allowable difference (error or distortion) in imaging devices (semiconductor devices), MTJs, manufacturing processes thereof, or use or operation thereof, and a shape similar to the shape.

In the following description of circuits (electrical connection), unless otherwise specified, “electrically connected” means that a plurality of elements is connected such that electricity (signal) is conducted. In addition, “electrically connected” in the following description includes not only a case where a plurality of elements is directly and electrically connected but also a case where a plurality of elements is indirectly and electrically connected via other elements.

Note that the description will be given in the following order.

### 1. Background of Elaboration of Embodiment of Present Disclosure

1.1 Imaging Device
1.2 MIJ Element
1.3 Background

### 2. Embodiment of Present Disclosure

2.1 Detailed Configuration
2.2 Manufacturing Method
2.3 Application Examples

### 3. Summary

### 4. Application Examples

4.1 Application Example to Camera
4.2 Application Example to Smartphone
4.3 Application Example to Mobile Device Control System

### 5. Supplements

### 1. BACKGROUND OF ELABORATION OF EMBODIMENT OF PRESENT DISCLOSURE

### 1.1 Imaging Device

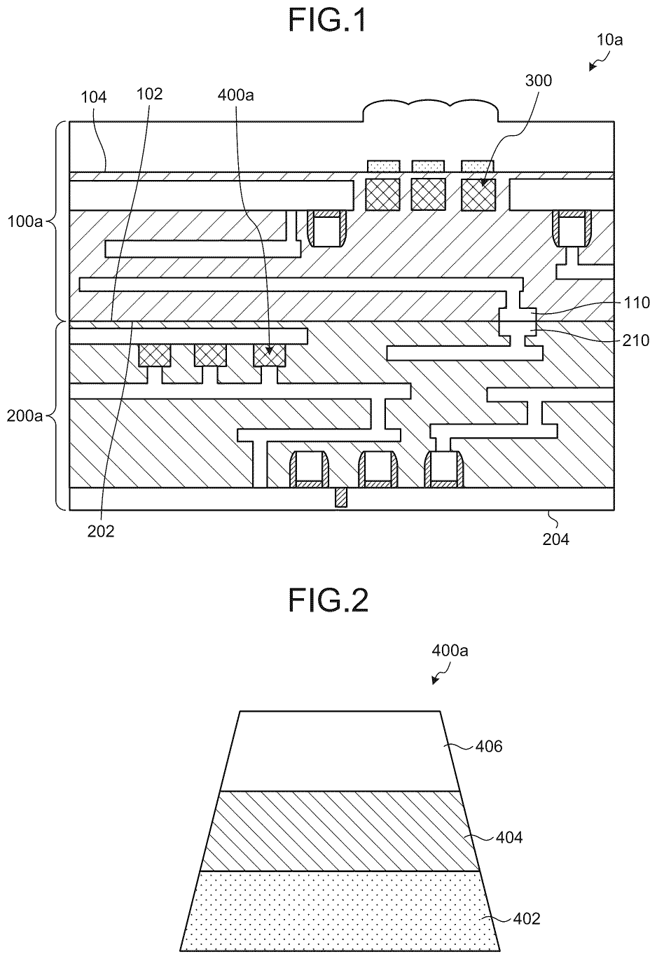

First, before describing an embodiment of the present disclosure, the background that led the present inventor to elaboration of the embodiment of the present disclosure will be described. First, a stacked structure of an imaging device 10a according to a comparative example will be described with reference to FIG. 1. FIG. 1 is an explanatory diagram schematically illustrating the stacked structure of the imaging device 10a of the comparative example. Note that, in this example, the comparative example means the imaging device 10a and a structure of a main part thereof that have been repeatedly examined by the inventor before devising the embodiment of the present disclosure.

As illustrated in FIG. 1, the imaging device 10a according to the comparative example is an imaging device having a three-dimensional structure including two semiconductor substrates (first semiconductor substrate 100a and second semiconductor substrate 200a) bonded to each other. Specifically, it is based on the premise that the imaging device 10a is a back-illuminated imaging device in which light is incident from the back surface (light incident surface) 104 side of the first semiconductor substrate 100a including photodiodes (imaging elements) 300.

Specifically, the first semiconductor substrate 100a includes a pixel region including a plurality of imaging elements 300 two-dimensionally arrayed on a plane. An imaging element 300 is a photodiode capable of generating a charge in response to light from the back surface (light incident surface) 104 of the first semiconductor substrate 100a and is electrically connected to a pixel circuit including a plurality of pixel transistors (not illustrated). The pixel circuit is provided on the first semiconductor substrate 100a and can read out a charge generated in a photodiode 300 as a pixel signal via a transfer transistor (not illustrated) and reset the photodiode 300.

Note that, in the comparative example, the imaging device 10a may include a semiconductor substrate (not illustrated) inserted between the first semiconductor substrate 100a and the second semiconductor substrate 200a, and the pixel circuit may be provided on the semiconductor substrate.

Meanwhile, the second semiconductor substrate 200a is provided with, for example, logic circuits such as an input unit, a row drive unit, a timing control unit, a column signal processing unit, an image signal processing unit, and an output unit in order to control the plurality of imaging elements 300 or to process signals from the plurality of imaging elements 300. Furthermore, the second semiconductor substrate 200a includes a memory area including a plurality of magnetic tunnel junction (MTJ) elements (memory elements) 400a two-dimensionally arrayed on a plane. The memory area stores signals used by the image signal processing unit or processed signals. Note that the detailed configuration of an MTJ element 400a according to the comparative example will be described later.

Furthermore, the first semiconductor substrate 100a and the second semiconductor substrate 200a are joined to each other in such a manner that a front surface 102 of the first semiconductor substrate 100a and a front surface 202 of the second semiconductor substrate 200a face each other. Specifically, the first semiconductor substrate 100a and the second semiconductor substrate 200a can be electrically connected by, for example, a through electrode (not illustrated). In addition, the first semiconductor substrate 100a and the second semiconductor substrate 200a have connecting portions 110 and 210 that electrically connect the first semiconductor substrate 100a and the second semiconductor substrate 200a. Specifically, the connecting portions 110 and 210 are formed of electrodes made of a conductive material, and by directly joining the connecting portions 110 and 210, the first semiconductor substrate 100a and the second semiconductor substrate 200a are electrically connected to each other, and signal input and/or output between the first semiconductor substrate 100a and the second semiconductor substrate 200a is enabled. The conductive material is, for example, a metal material such as copper (Cu), aluminum (Al), or gold (Au).

### <1.2 MIJ Element>

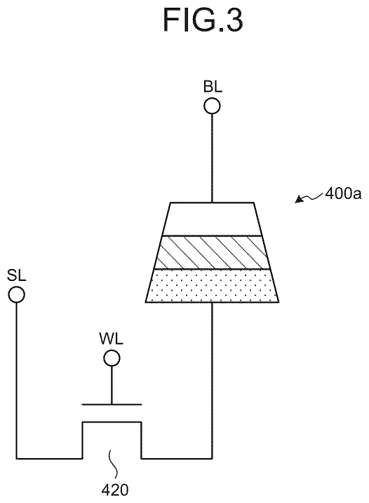

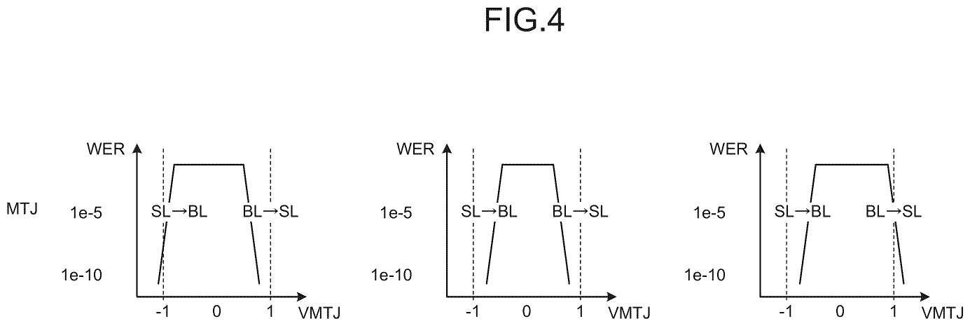

Next, the MTJ elements 400a included in the second semiconductor substrate 200a described above will be described with reference to FIGS. 2 and 3. FIG. 2 is an explanatory view schematically illustrating a stacked structure of an MIJ element 400a according to the comparative example and, specifically, an enlarged view of the MTJ element 400a in the cross-sectional view of FIG. 1. The upper side of FIG. 2 is the front surface 202 side of the second semiconductor substrate 200a, and the lower side of FIG. 2 is a back surface 204 side of the second semiconductor substrate 200a. Furthermore, FIG. 3 is an explanatory diagram schematically illustrating a circuit configuration of the MIJ element 400a according to a comparative example.

A magnetic random access memory (MRAM) stores information by using a change in electric resistance by changing a magnetization state of a magnetic body of a magnetic storage element included in the MRAM. Therefore, the stored information can be read by determining the resistance state of the magnetic storage element determined by the change in the magnetization state, specifically, the magnitude of the electric resistance of the magnetic storage element. Such an MRAM can perform high-speed operation, can be overwritten almost infinitely (1015 times or more), and is highly reliable.

A basic structure of the MTJ element 400a, which is the magnetic storage element of the MRAM, will be described with reference to FIGS. 2 and 3. For example, the MIJ element 400a is a magnetic storage element that stores one piece of information (1 or 0). Address wires (namely, a word line and a bit line) (not illustrated) orthogonal to each other are provided above and below the MTJ element 400a, and the MTJ element 400a is connected to the word line and the bit line in the vicinity of an intersection of these wires.

Specifically, as illustrated in FIG. 2, the MTJ element 400a has a structure in which a fixed layer (magnetization fixed layer) 402 in which a magnetic moment is fixed in a predetermined direction, a nonmagnetic layer 404, a storage layer 406 in which the direction of the magnetic moment is variable, and a cap layer (not illustrated) are sequentially stacked on a base layer (not illustrated). In other words, the MTJ element 400a has a bottom Pin structure in which the fixed layer (Pin layer) 402 is located at the bottom. In general, in order to avoid deterioration of the storage characteristics of the MIJ element 400a due to processing, it is preferable to position the fixed layer 402 at the bottom. Therefore, in the comparative example, in the case where the front surface 202 of the second semiconductor substrate 200a facing the first semiconductor substrate 100a faces upward, the lowest layer of the MIJ element 400a is the fixed layer 402.

The fixed layer 402 is formed of a magnetic body containing a ferromagnetic material, and the direction of the magnetic moment is fixed by a high coercive force or the like. The nonmagnetic layer 404 is formed of various nonmagnetic bodies such as magnesium oxide (MgO) and is included between the fixed layer 402 and the storage layer 406. The storage layer 406 is formed of a magnetic body containing a ferromagnetic material, and the direction of the magnetic moment changes depending on information to be stored. Furthermore, the base layer and the cap layer function as an electrode, a control film of crystal orientation, a protective film, and the like. In the MTJ element 400a, by applying a voltage to the MIJ element 400a to change the direction of the magnetic moment of the storage layer 406, the resistance value of the entire MIJ element 400a changes due to a difference from the direction of the magnetic moment of the fixed layer 402. Specifically, in a case where the directions of the magnetic moments of the fixed layer 402 and the storage layer 406 are the same, the resistance value of the MTJ element 400a is low, and in a case where the directions of the magnetic moments of the fixed layer 402 and the storage layer 406 are different, the resistance value of the MIJ element 400a is high. Moreover, the MIJ element 400a can store information using a change in the resistance value due to such a change in the magnetic moment.

Furthermore, although not illustrated in FIG. 2, the MTJ element 400a is sandwiched between an upper electrode (first electrode) and a lower electrode (not illustrated) and is electrically connected to a word line, a bit line, a signal line, a selection transistor 420 (see FIG. 3), and the like via these electrodes.

Specifically, as illustrated in FIG. 3, the fixed layer (magnetization fixed layer) 402 of the MTJ element 400a is electrically connected with the word line WL and the signal line SL via the lower electrode (not illustrated) and the selection transistor 420, and the storage layer 406 of the MTJ element 400a is electrically connected with the bit line BL via the upper electrode (not illustrated). As a result, in the MIJ element 400a selected by the selection transistor 420, a voltage is applied between the lower electrode and the upper electrode of the MIJ element 400a via the signal line SL and the bit line BL, whereby information is written to and read from the storage layer 406 of the MIJ element 400a.

### <1.3 Background>

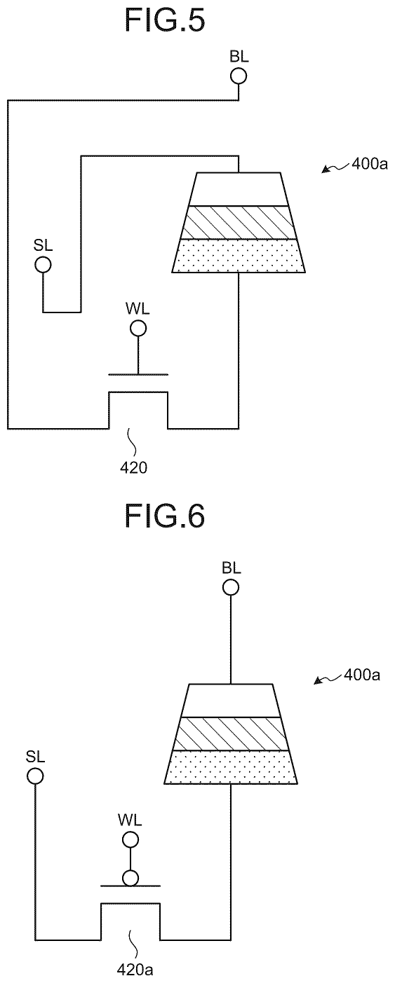

With reference to FIGS. 4 to 7, the background having led to the elaboration of the embodiment of the present disclosure by the inventor will be described on the basis of the imaging device 10a of the aforementioned comparative example. FIGS. 4 to 7 are explanatory diagrams for explaining the background having led to the elaboration of the embodiment of the present disclosure.

Meanwhile, due to the characteristics of the MIJ element 400a, three patterns illustrated in FIG. 4 are assumed for the relationship between the voltage applied to the MTJ element 400a and the error rate at the time of data writing. In FIG. 4, the horizontal axis represents the voltage applied to the MTJ element 400a, and the vertical axis represents the error rate of data writing. Furthermore, in FIG. 4, when the voltage applied to the MIJ element 400 is changed from −1 to 0, a write current flows from the signal line SL towards the bit line BL, and when the applied voltage is changed from 0 to 1, a write current flows from the bit line BL towards the signal line SL.

Among the three patterns illustrated in FIG. 4, ideally, the MTJ element 400a preferably has a pattern illustrated in the center that can sufficiently lower the error rate within the applied voltage width. Specifically, the MIJ element 400a preferably has a characteristic that a sufficiently low error rate (1e⁻¹⁰) is obtained in a case where a predetermined voltage (−1, 1) is applied to the MIJ element 400a. However, in consideration of the characteristics of materials included in the MIJ element 400a and variations in the quality of the MTJ element 400a and others in mass production, it is difficult to obtain an MTJ element 400a having such a characteristic as the pattern illustrated in the center.

Specifically, in a case of the pattern illustrated on the left side of FIG. 4, even if a predetermined voltage (−1) is applied when a write current flows from the signal line SL towards the bit line BL, a sufficiently low error rate (1e⁻¹⁰) is not obtained. In this case, since the MIJ element 400a is source-connected with the selection transistor 420 (see FIG. 3), even if the voltages of the word line WL and the signal line SL are increased, the current driving capability of the selection transistor 420 is low, and thus it is difficult to apply a sufficient voltage to the MIJ element 400a.

Meanwhile, in the case of the pattern illustrated on the right side of FIG. 4, even if a predetermined voltage (1) is applied when the write current flows from the bit line BL to the signal line SL, a sufficiently low error rate (1e⁻¹⁰) is not obtained. In this case, the MTJ element 400a is drain-connected to the selection transistor 420 (see FIG. 3), and the current driving capability of the selection transistor 420 is high. Therefore, by increasing the voltages of the word line WL and the signal line SL, it is easy to apply a sufficient voltage to the MTJ element 400a.

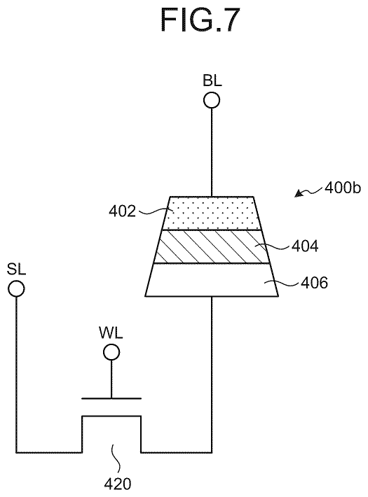

Therefore, in order to avoid the pattern illustrated on the left side of FIG. 4, for example, it is conceivable to switch the wire connection of the MIJ element 400a as illustrated in FIG. 5. Specifically, the fixed layer 402 of the MTJ element 400a is electrically connected to the bit line BL via the selection transistor 420, and the storage layer 406 of the MIJ element 400a is electrically connected to the signal line SL. However, in the example of FIG. 5, since the wires and others are routed, it is inevitable that the sizes of the MTJ element 400a and a circuit connected thereto increase.

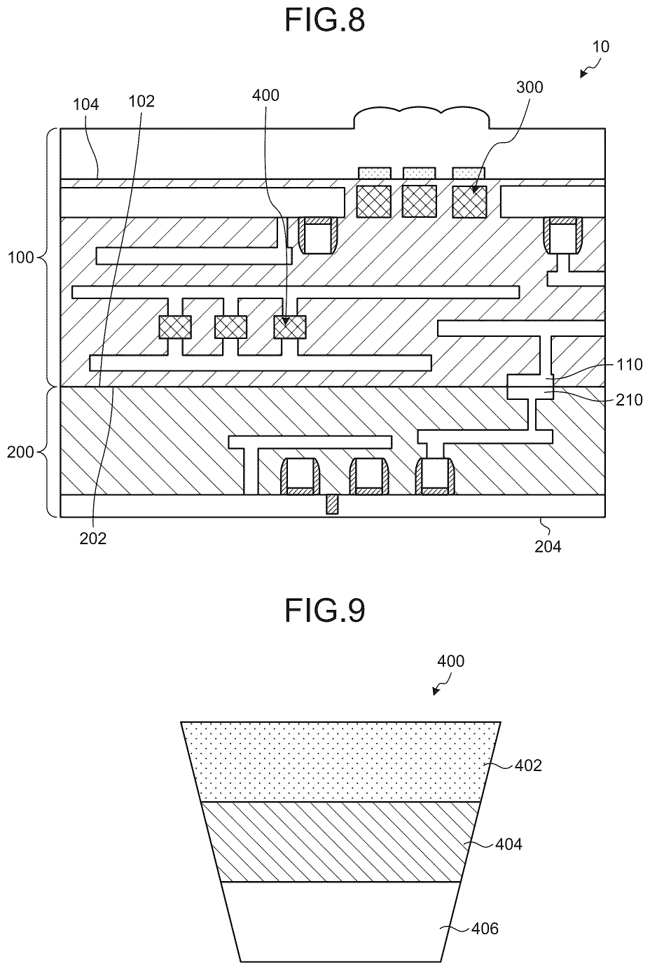

Furthermore, for example, as illustrated in FIG. 6, it is conceivable to change the connection form between the MIJ element 400a and the selection transistor 420 a by changing the selection transistor to a p-type MOS transistor 420a. However, since the p-type MOS transistor 420a has low current driving capability, it is necessary to increase the cell size.

Therefore, even in the example of FIG. 6, it is inevitable that the size of a circuit connected to the MIJ element 400a increases.

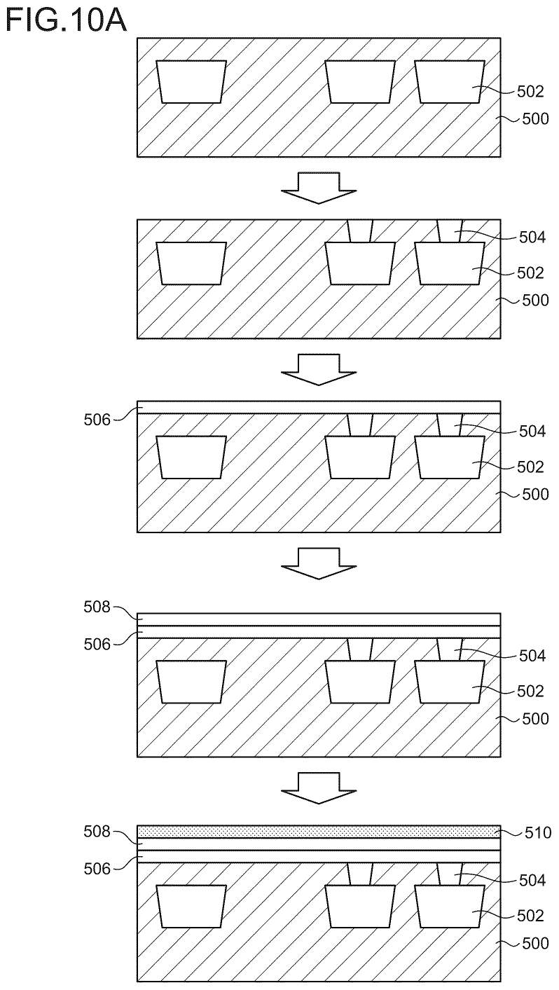

Furthermore, for example, as illustrated in FIG. 7, it is conceivable to change the MIJ element 400a to an MTJ element 400b having a top Pin structure. Specifically, as illustrated in FIG. 7, the MTJ element 400b has a structure in which a storage layer 406, a nonmagnetic layer 404, and a fixed layer 402 are sequentially stacked. With this structure, when the write current flows from a signal line SL towards a bit line BL, even in the source connection in which the current driving capability of a selection transistor 420 is lowered, the current easily flows to the MTJ element 400b since the resistance value of the MTJ element 400b is low (directions of magnetic moments are the same). As a result, it becomes easy to apply a sufficient voltage to the MTJ element 400b.

However, in the top Pin structure in which the storage layer 406, the nonmagnetic layer 404, and the fixed layer 402 are sequentially stacked, the fixed layer 402 is likely to be damaged during processing of the MTJ element 400b, and it is conceivable that no MTJ element 400b having desired storage characteristics can be obtained.

Therefore, in view of such a situation, the present inventor has elaborated the embodiment of the present disclosure capable of easily forming an imaging device 10 including MTJ elements 400 having a small cell size, a small circuit scale, and the like and a sufficiently low error rate at a predetermined applied voltage while avoiding damaging a fixed layer 402. Hereinafter, details of the embodiment of the present disclosure elaborated by the present inventor will be described in order.

Note that, in the following description, a case where the embodiment of the present disclosure is applied to an imaging device 10 will be described as an example. However, the present embodiment is not limited to being applied to the imaging device 10 and can be applied to any semiconductor device having a stacked structure.

### 2. EMBODIMENT OF PRESENT DISCLOSURE

### 2.1 Detailed Configuration

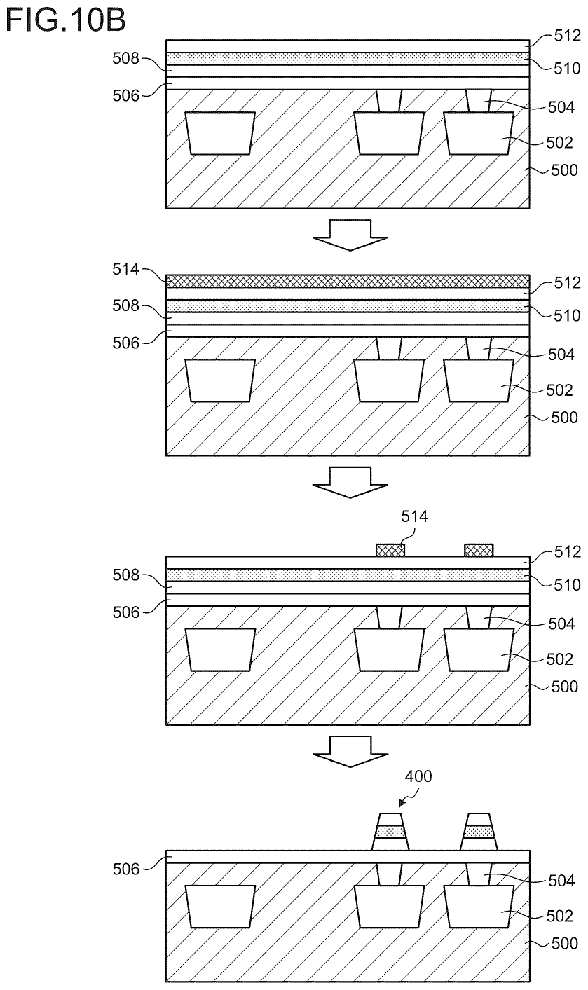

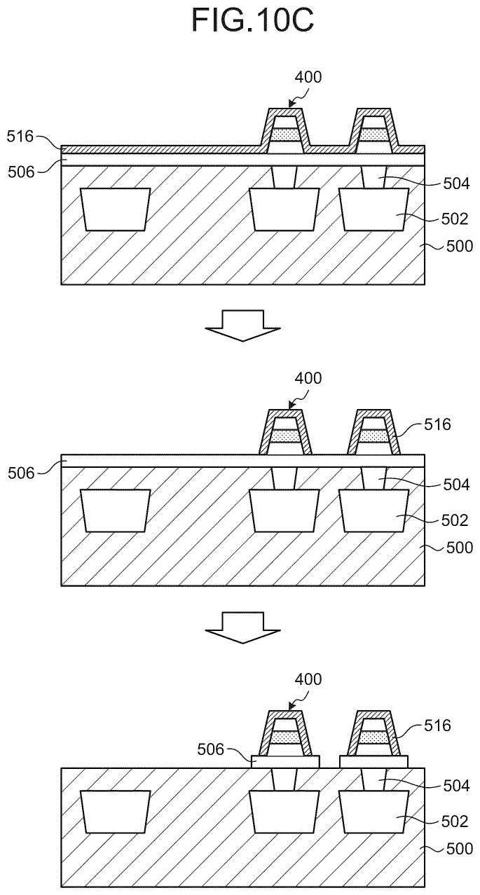

First, a detailed configuration of the imaging device (semiconductor device) 10 and an MTJ element 400 according to the embodiment of the present disclosure will be described with reference to FIGS. 8 and 9. FIG. 8 is an explanatory diagram schematically illustrating a stacked structure of the imaging device 10 according to the present embodiment. Furthermore, FIG. 9 is an explanatory diagram schematically illustrating a stacked structure of the MIJ element 400 according to the embodiment and, specifically, an enlarged view of the MIJ element 400 in the cross-sectional view of FIG. 8. The upper side of FIG. 9 is a back surface 104 of a first semiconductor substrate 100, and the lower side of FIG. 9 is a front surface 102 of the first semiconductor substrate 100.

### (Imaging Device)

As illustrated in FIG. 8, the imaging device 10 according to the embodiment is an imaging device having a three-dimensional structure including two semiconductor substrates (first semiconductor substrate 100 and second semiconductor substrate 200) bonded to each other similarly to the comparative example. Specifically, it is based on the premise that the imaging device 10 is a back-illuminated imaging device in which light is incident from the back surface (light incident surface) 104 side of the first semiconductor substrate 100 including photodiodes (imaging elements) 300.

Specifically, the first semiconductor substrate 100 includes a pixel region including a plurality of imaging elements 300 two-dimensionally arrayed on a plane similarly to the comparative example. An imaging element 300 is a photodiode capable of generating a charge in response to light from the back surface (light incident surface) 104 of the first semiconductor substrate 100 and is electrically connected to a pixel circuit including a plurality of pixel transistors (not illustrated).

Furthermore, in the present embodiment, unlike in the comparative example, the first semiconductor substrate 100 includes a memory area including a plurality of magnetic tunnel junction (MTJ) elements (first memory elements) 400 two-dimensionally arrayed on a plane. The memory area is provided on the front surface 102 side located on the opposite side of the back surface 104 of the first semiconductor substrate 100 with respect to the above-described pixel region. In addition, the memory area stores signals used by an image signal processing unit or processed signals. Note that a detailed configuration of the MIJ element 400 according to the embodiment will be described later.

Furthermore, also in the present embodiment, similarly to the comparative example, the second semiconductor substrate 200 is provided with, for example, logic circuits such as an input unit, a row drive unit, a timing control unit, a column signal processing unit, an image signal processing unit, and an output unit in order to control the plurality of imaging elements 300 or to process signals from the plurality of imaging elements 300.

Furthermore, also in the present embodiment, the first semiconductor substrate 100 and the second semiconductor substrate 200 are joined to each other in such a manner that the front surface 102 of the first semiconductor substrate 100 and a front surface 202 of the second semiconductor substrate face each other. Specifically, the first semiconductor substrate 100 and the second semiconductor substrate 200 can be electrically connected by, for example, a through electrode (not illustrated). In addition, the first semiconductor substrate 100 and the second semiconductor substrate 200 have connecting portions (junction electrodes) 110 and 210 that electrically connect the first semiconductor substrate 100 and the second semiconductor substrate 200. Specifically, the connecting portions 110 and 210 are formed of electrodes made of a conductive material, and by directly joining the connecting portions 110 and 210, the first semiconductor substrate 100 and the second semiconductor substrate 200 are electrically connected to each other, and signal input and/or output between the first semiconductor substrate 100 and the second semiconductor substrate 200 is enabled. The conductive material is, for example, a metal material such as copper (Cu), aluminum (Al), or gold (Au).

### (MTJ Element)

As illustrated in FIG. 9, the MIJ element 400 according to the present embodiment has a structure in which a storage layer 406 in which the direction of a magnetic moment is variable, a nonmagnetic layer 404, and a fixed layer (magnetization fixed layer) 402 in which the magnetic moment is fixed in a predetermined direction are sequentially stacked on a base layer (not illustrated). That is, the MIJ element 400 according to the embodiment has a top Pin structure in which a stack is layered in an order different from that of the MIJ element 400a according to the comparative example, and the fixed layer (Pin layer) 402 is located at the top. As described above, in general, in order to avoid deterioration of the storage characteristics of the MIJ element 400 due to processing, it is preferable to position the fixed layer 402 at the bottom. Meanwhile, in the present embodiment, the MIJ element 400 employs the top Pin structure in which the fixed layer (Pin layer) 402 is located at the top.

Furthermore, although not illustrated in FIG. 9, the MTJ element 400 is sandwiched between an upper electrode (first electrode) (not illustrated) and a lower electrode (second electrode) (not illustrated) similarly to the comparative example and is electrically connected with a word line, a bit line, a signal line, a selection transistor 420, and the like via these electrodes. Specifically, the storage layer 406 of the MTJ element 400 is electrically connected with a word line WL and a signal line SL via the selection transistor 420 including a lower electrode (not illustrated) and an n-type metal-oxide-semiconductor (MOS) transistor, and the fixed layer (magnetization fixed layer) 402 of the MTJ element 400 is electrically connected with the bit line BL via the upper electrode (not illustrated) (similarly to the MIJ element 400b illustrated in FIG. 7). As a result, in the MIJ element 400 selected by the selection transistor 420, a voltage is applied between the lower electrode and the upper electrode of the MTJ element 400 via the word line WL and the bit line BL, whereby information is written to and read from the storage layer 406 of the MIJ element 400.

In the present embodiment, by providing the MTJ element 400 having the top Pin structure, when the write current flows from the signal line SL towards the bit line BL, even in the source connection in which the current driving capability of the selection transistor 420 is lowered, the current easily flows to the MIJ element 400 since the resistance value of the MTJ element 400 is low (directions of magnetic moments are the same). Therefore, it becomes easy to apply a sufficient voltage to the MTJ element 400, and the error rate becomes sufficiently low at a predetermined applied voltage.

Furthermore, specifically, as illustrated in FIG. 9, a cross section cut along the stacking direction of the MIJ element 400 has a trapezoidal shape, and the length of the upper base of the trapezoid located on the back surface (light incident surface) 104 side of the first semiconductor substrate 100 is longer than the length of the lower base of the trapezoid. Note that, in the present embodiment, the cross-sectional shape of the MTJ element 400 has been described as being trapezoidal due to processing; however, it is not limited thereto. For example, the cross-sectional shape of the MTJ element 400 may be rectangular or may be a trapezoidal shape in which the length of the upper base located on the back surface (light incident surface) 104 side of the first semiconductor substrate 100 is shorter than the length of the lower base of the trapezoid.

Also in the present embodiment, similarly to the comparative example, the fixed layer 402 is formed of a magnetic body containing a ferromagnetic material, and the direction of the magnetic moment is fixed by a high coercive force or the like. The nonmagnetic layer 404 is formed of various nonmagnetic bodies such as magnesium oxide (MgO) and is included between the fixed layer 402 and the storage layer 406. The storage layer 406 is formed of a magnetic body containing a ferromagnetic material, and the direction of the magnetic moment changes depending on information to be stored.

### <2.2 Manufacturing Method>

### (MTJ Element)

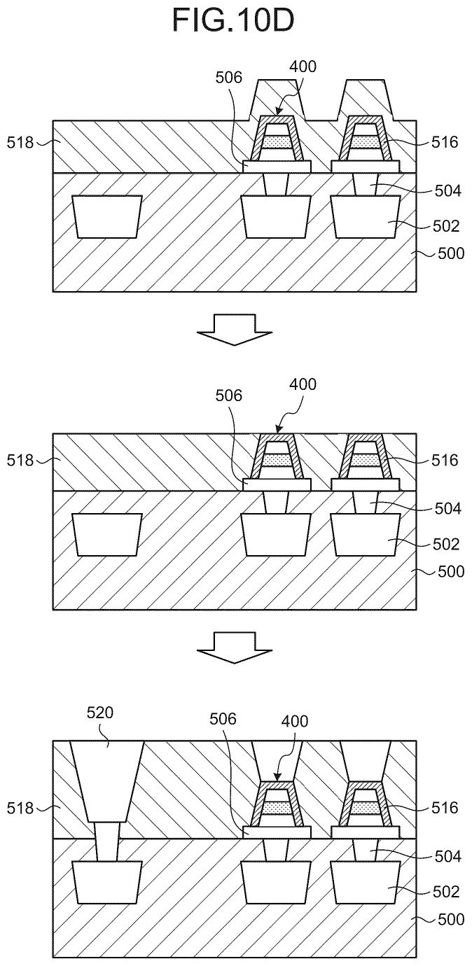

Next, a manufacturing method of the MTJ element 400 according to the embodiment will be described with reference to FIGS. 10A to 10D. FIGS. 10A to 10D are cross-sectional views in one step of the manufacturing method of the MTJ element 400 according to the present embodiment. Note that, in these drawings, only a main part of the embodiment is illustrated, and illustration of other elements and others is omitted to facilitate understanding.

First, as illustrated in the first row of FIG. 10A, a substrate in which lower wiring 502 is included in an insulating film 500 is prepared, and as illustrated in the second row from the top of FIG. 10A, a damascene structure (structure in which a metal material is embedded in a groove) 504 electrically connected with the lower wiring 502 is formed.

Then, as illustrated in the third row from the top in FIG. 10A, a barrier metal film 506 is formed on the damascene structure 504 and the insulating film 500. Next, as illustrated in the fourth row from the top in FIG. 10A, an electrode 508 is formed on the barrier metal film 506. Furthermore, as illustrated in the last row of FIG. 10A, an MTJ layer 510 included in the MIJ element 400 according to the embodiment is formed on the electrode 508. Specifically, the MIJ layer 510 is formed on the electrode 508 in the order of the fixed layer 402, the nonmagnetic layer 404, and the storage layer 406.

First, as illustrated in the first row of FIG. 10B, an electrode 512 is formed on the MIJ layer 510. Next, as illustrated in the second row from the top in FIG. 10B, a hardmask 514 is formed on the electrode 512.

Then, as illustrated in the third row from the top in FIG. 10B, the hardmask 514 is processed into a predetermined pattern using a means such as lithography. Furthermore, as illustrated in the last row of FIG. 10B, the MTJ layer 510 and the electrodes 508 and 512 are processed by etching in accordance with the pattern of the hardmask 514 to form MTJ elements 400.

Next, as illustrated in the first row of FIG. 10C, a protective film 516 made of an insulating material is formed in such a manner as to cover the MIJ elements 400 and the barrier metal film 506. Next, as illustrated in the second row from the top in FIG. 10C, the protective film 516 is removed in such a manner that the protective film 516 covers only the upper surfaces and the side surfaces of the MIJ elements 400. Furthermore, as illustrated in the last row of FIG. 10C, the barrier metal film 506 is removed in such a manner that the barrier metal film 506 remains only under the MIJ elements 400.

Next, as illustrated in the first row of FIG. 10D, an interlayer insulating film 518 is formed in such a manner as to cover the MTJ elements 400 and the insulating film 500.

Furthermore, the interlayer insulating film 518 is planarized using a method such as chemical mechanical polishing (CMP) in such a manner that the upper surface of the interlayer insulating film 518 is flush with the upper surface of the MIJ elements 400. Then, as illustrated in the last row of FIG. 10, wiring 520 is formed in the interlayer insulating film 518. In this manner, the MTJ element 400 according to the embodiment can be formed.

### (Imaging Device)

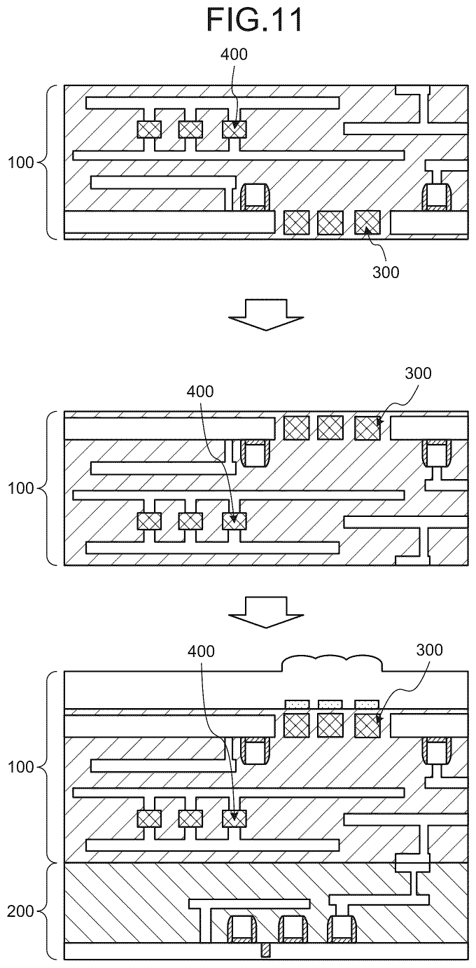

Furthermore, a manufacturing method of the imaging device 10 according to the embodiment will be described with reference to FIG. 11. FIG. 11 is a cross-sectional view in one step of the manufacturing method of the imaging device 10 according to the embodiment.

First, as illustrated in the first row of FIG. 11, the first semiconductor substrate 100 in which the MIJ elements 400 are formed as described above is prepared. Next, as illustrated in the second row from the top in FIG. 11, the first semiconductor substrate 100 is turned upside down. Furthermore, as illustrated in the last row of FIG. 11, the inverted first semiconductor substrate 100 and the second semiconductor substrate provided with logic circuits are joined, and a color filter, an on-chip lens, and others are formed on the upper surface of the imaging device 10, whereby the imaging device 10 is formed.

As described above, in the present embodiment, even in the case where the MIJ elements 400 having the top Pin structure are included, the fixed layer 402, the nonmagnetic layer 404, and the storage layer 406 are stacked in the order mentioned at the time of forming the MTJ elements 400, and thus it is possible to avoid damaging the fixed layer 402 at the time of processing the MTJ elements 400. Therefore, the MIJ elements 400 having desired storage characteristics can be easily obtained. In addition, in the present embodiment, since the MIJ elements 400 are included in the first semiconductor substrate 100 instead of the second semiconductor substrate 200 in which the logic circuits are included, the MIJ elements 400 are not restricted by the arrangement of the logic circuits and are not affected by heat nor stress applied when the logic circuits are formed.

Furthermore, in the present embodiment, since such MIJ elements 400 are formed on the first semiconductor substrate 100, then inverted upside down, and joined to the second semiconductor substrate 200, the MTJ elements 400 can be connected with the logic circuits of the second semiconductor substrate 200 in the same manner as the conventional bottom Pin structure.

As described above, according to the present embodiment, it is possible to easily form the imaging device 10 including the MTJ elements 400 having a small cell size, a small circuit scale, and the like and a sufficiently low error rate at a predetermined applied voltage while avoiding damaging the fixed layers 402. In other words, according to the embodiment, it is possible to easily form the imaging device 10 having a three-dimensional structure including the MIJ elements 400 having a small cell size, a small circuit scale, and the like and having favorable characteristics.

### <2.3 Application Examples>

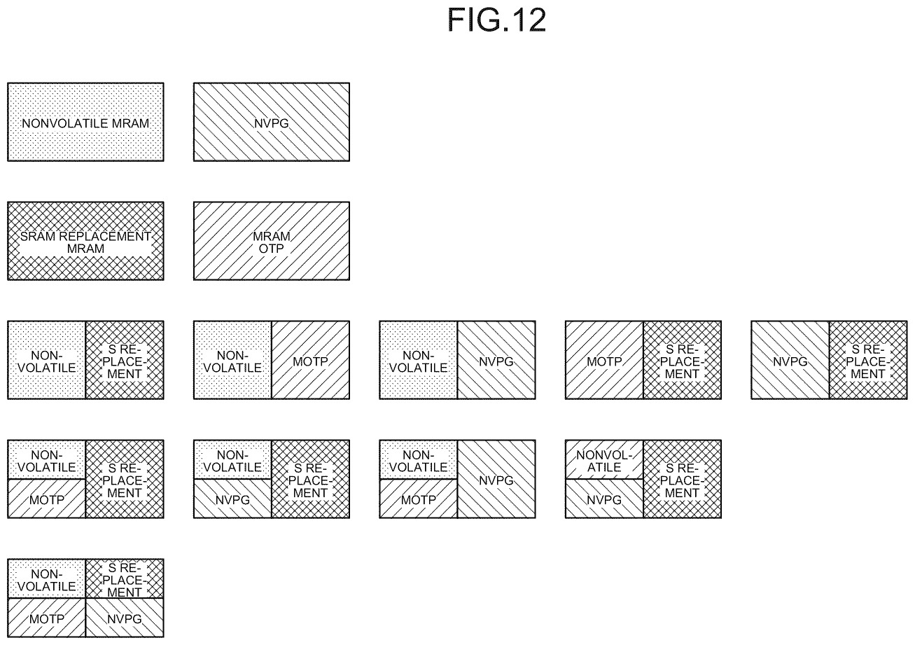

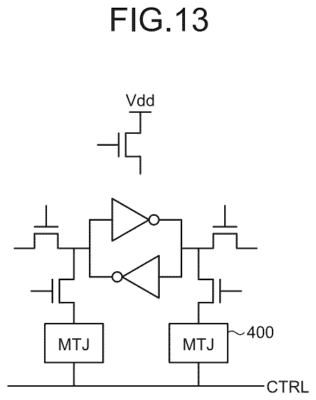

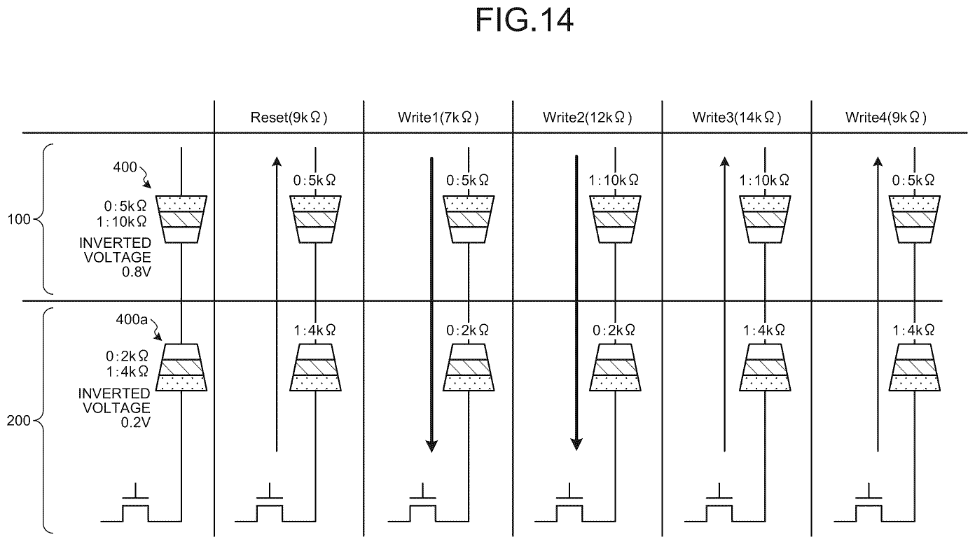

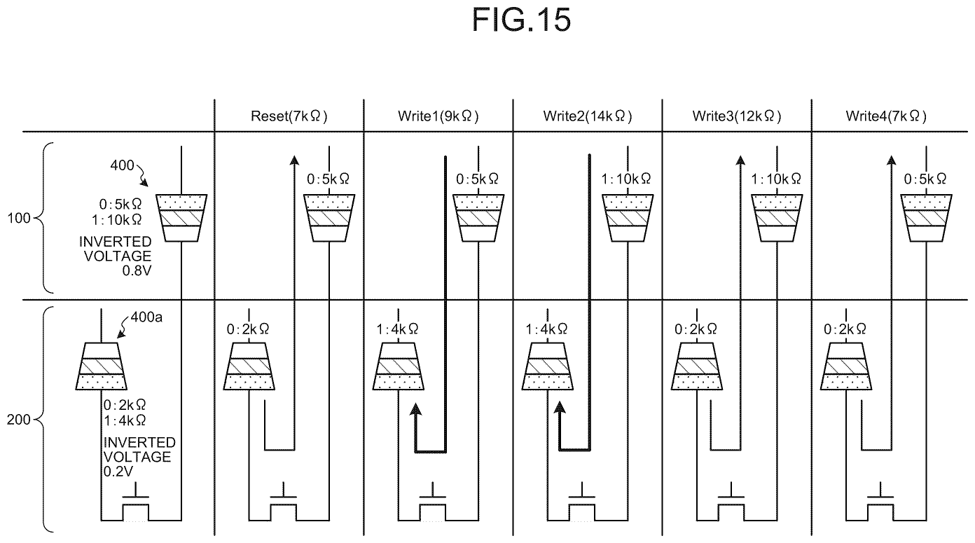

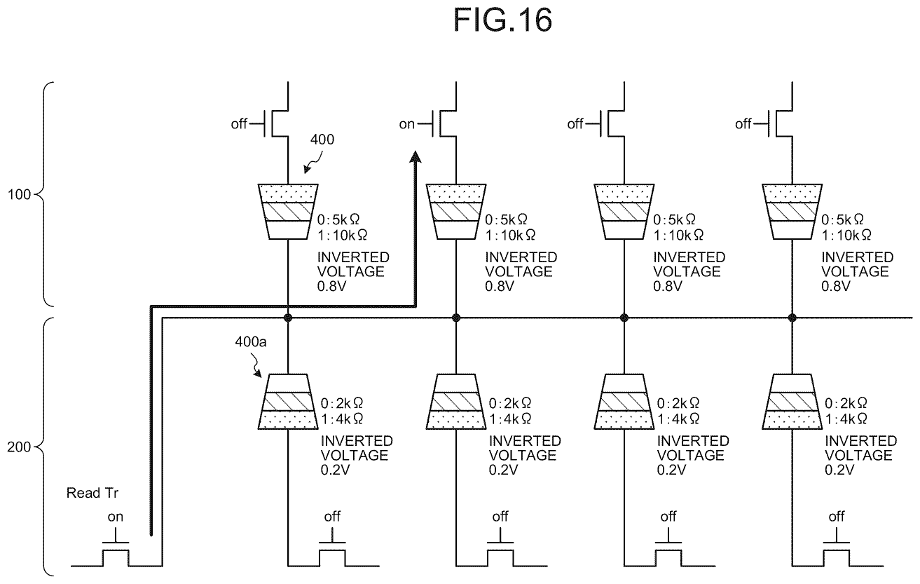

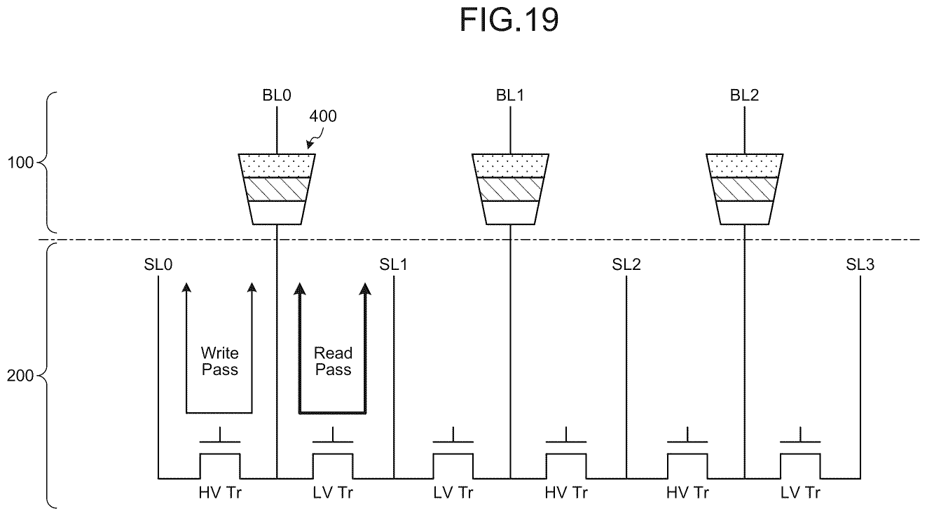

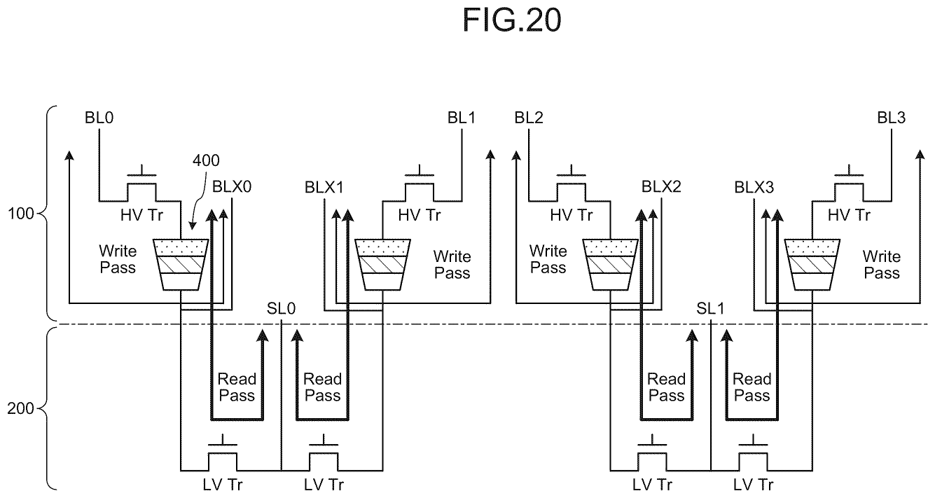

In the present embodiment, the memory area including the plurality of MTJ elements 400 included in the first semiconductor substrate 100 may include various storage elements. Therefore, application examples of such a memory area will be described with reference to FIGS. 12 to 20. FIG. 12 is an explanatory diagram illustrating a modification of the memory area according to the embodiment, and FIG. 13 is an explanatory diagram illustrating an example of a circuit of a memory layer according to the embodiment. Furthermore, FIGS. 14 and 15 are explanatory diagrams illustrating a configuration of an imaging device 10 according to a modification of the present embodiment, and FIGS. 16 to 18 are explanatory diagrams illustrating a control example of an imaging device 10 according to the modification of the embodiment. Furthermore, FIGS. 19 and 20 are explanatory diagrams illustrating circuit configuration examples of the MTJ elements 400 according to the modification of the embodiment of the present disclosure.

As illustrated in FIG. 12, the memory area according to the embodiment may include various storage elements depending on a writing speed, an allowable number of times of writing, power consumption, a circuit scale, a storage density, and the like. For example, the memory area according to the embodiment may include a nonvolatile MRAM (also referred to as “nonvolatile” in FIG. 12) including an MTJ element 400 as a nonvolatile storage element. Furthermore, the nonvolatile storage element may include a one-time programmable (OTP) storage element that can perform writing only once due to destruction of a nonmagnetic layer 404 (in FIG. 12, also referred to as “MRAMOTP” or “MOTP”). Furthermore, for example, the memory area according to the embodiment may include an MTJ element 400 as a volatile storage element. Furthermore, the memory area according to the embodiment may include a logic circuit. For example, the memory area according to the embodiment may include a static random access memory (SRAM) having a volatile storage element (in FIG. 12, also referred to as “SRAM replacement MRAM” or “S replacement”). Furthermore, the memory area may be a nonvolatile power gating (NVPG) including an MTJ element 400 as a nonvolatile storage element and a bistable storage circuit (nonvolatile logic circuit), and data can be held even when the power supply is shut off. Specifically, the NVPG includes, for example, a circuit as illustrated in FIG. 13 and has a configuration in which the MIJ element 400 as a nonvolatile element is electrically connected to a latch unit of the logic circuit. In the NVPG, data written in the latch unit can be written in the MTJ element 400 when the power supply is shut off, and the data in the MIJ element 400 can be returned to the latch unit when the power supply is connected, whereby the power consumption can be suppressed to a low level.

In the embodiment described above, it has been described that the MTJ elements 400 are included only in the semiconductor substrate (first semiconductor substrate) 100; however, in the present embodiment of the disclosure, MIJ elements 400 may be included in both of two semiconductor substrates (first semiconductor substrate and second semiconductor substrate) 100 and 200.

For example, as illustrated in FIG. 14, the semiconductor substrate 200 may include a plurality of MIJ elements (second memory elements) 400a. Specifically, an MIJ element 400 included in the semiconductor substrate 100 and an MTJ element 400a included in the semiconductor substrate 200 are connected in series to a terminal on one side of a selection transistor. In this example, one MIJ element 400 and one MTJ element 400a connected in series with each other are referred to as a memory element pair. Furthermore, in the example of FIG. 14, a plurality of memory element pairs is provided in an imaging device 10, and the plurality of memory element pairs are formed in such a manner as to have different resistance values from each other. In other words, the imaging device 10 has multi-value memory elements.

Alternatively, for example, as illustrated in FIG. 15, an MTJ element 400 included in the semiconductor substrate 100 and an MIJ element 400a included in the semiconductor substrate 200 are connected in series via a selection transistor.

Furthermore, as illustrated in FIGS. 14 and 15, the MTJ elements 400a included in the semiconductor substrate 200 preferably have a bottom Pin structure. Specifically, an MTJ element 400a preferably has a stacked structure in which a storage layer 406 in which the direction of the magnetic moment is variable, a nonmagnetic layer 404, and a fixed layer (magnetization fixed layer) 402 in which the magnetic moment is fixed in a predetermined direction are stacked in the order mentioned from the semiconductor substrate 100 side.

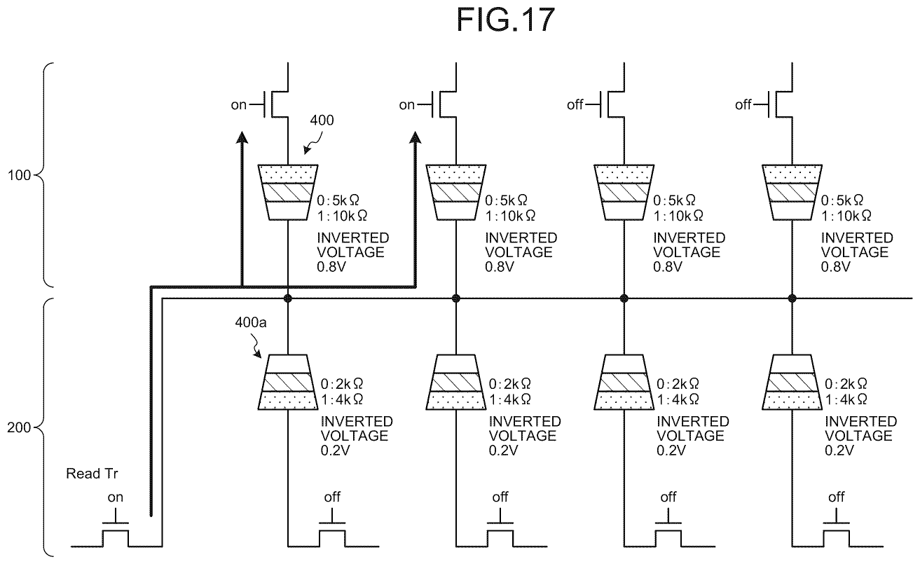

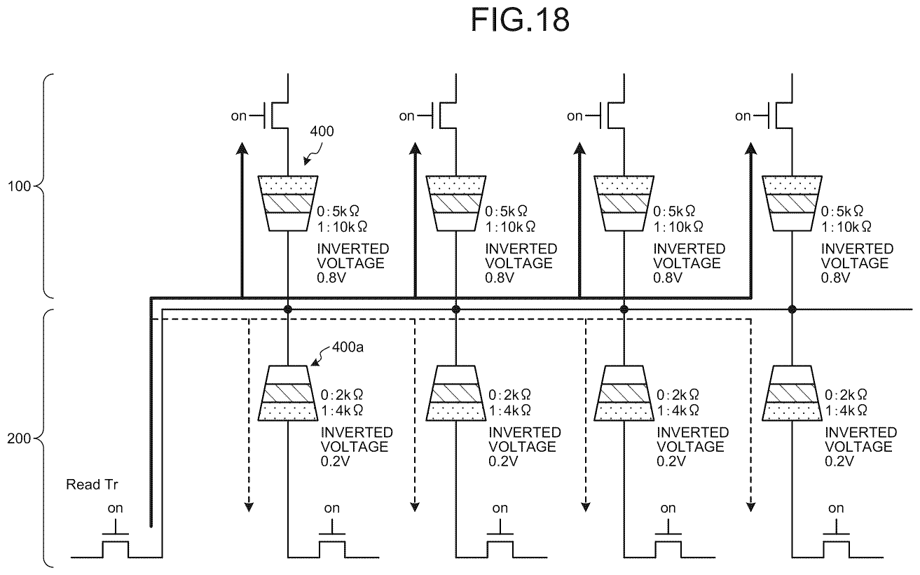

Further alternatively, as illustrated in FIGS. 16 to 18, an MTJ element 400 included in the semiconductor substrate 100 and an MIJ element 400a included in the semiconductor substrate 200 may be connected in such a manner as to be interposed between two selection transistors. Specifically, in the examples illustrated in FIGS. 16 to 18, the MTJ elements 400 and 400a to be read from may be controlled by turning on/off the selection transistors, and resistance values of the MTJ elements 400 and 400a may be read as analog values by read transistors. For example, as illustrated in FIGS. 16 and 17, reading may be performed from one or a plurality of MTJ elements 400, in other words, reading may be performed from MTJ elements included in one of the semiconductor substrates. Furthermore, as illustrated in FIG. 18, reading may be performed from both the MIJ elements 400 and the MIJ elements 400a.

Note that, in the examples illustrated in FIGS. 16 to 18, the semiconductor substrate 100 may include MTJ elements 400 having the top Pin structure, which are nonvolatile storage elements, and the semiconductor substrate 200 may include MTJ elements 400a having the static random access memory (SRAM) replacement or the bottom Pin structure, or the types of memory elements may be switched between the semiconductor substrate 100 and the semiconductor substrate 200.

Furthermore, in the embodiment of the present disclosure, as illustrated in FIGS. 19 and 20, an MTJ element 400 may be electrically connected with a read transistor and a write transistor. Specifically, as illustrated in FIGS. 19 and 20, the write transistors are preferably a high breakdown voltage transistor (HV Tr) that is not destroyed even when a high voltage is applied due to a thickened gate oxide film. Meanwhile, the read transistors are preferably a low breakdown voltage transistor (LV Tr) having a thinner gate oxide film than that of the write transistor and capable of conducting a large current even at a low voltage. Note that it is preferable to cause a current to flow through the read transistors in a direction in which an increase in the read error is suppressed.

### 3. SUMMARY

As described above, according to the present embodiment of the disclosure, it is possible to easily form the imaging device 10 including the MIJ elements 400 having a small cell size, a small circuit scale, and the like and a sufficiently low error rate at a predetermined applied voltage while avoiding damaging the fixed layers 402. In other words, according to the embodiment, it is possible to easily form the imaging device 10 having a three-dimensional structure including the MIJ elements 400 having a small cell size, a small circuit scale, and the like and having favorable characteristics.

In the embodiment of the disclosure described above, the case where the present disclosure is applied to a back-illuminated CMOS image sensor structure has been described; however, the embodiment of the present disclosure is not limited thereto and may be applied to a structure of another semiconductor device.

Furthermore, the imaging device 10 and the MTJ elements 400 according to the embodiment of the present disclosure can be manufactured by using a method, an apparatus, and conditions used for manufacturing a general semiconductor device. That is, the imaging device 10 and the MTJ elements 400 according to the embodiment can be manufactured using manufacturing steps of existing semiconductor devices.

Note that examples of the above-described method include a physical vapor deposition (PVD) method, a chemical vapor deposition (CVD) method, and an atomic layer deposition (ALD) method. Examples of the PVD method include a vacuum vapor deposition method, an electron beam (EB) vapor deposition method, various sputtering methods (magnetron sputtering method, radio frequency (RF)-direct current (DC) coupled bias sputtering method, electron cyclotron resonance (ECR) sputtering method, counter target sputtering method, radio frequency sputtering method, and the like), an ion plating method, a laser ablation method, a molecular beam epitaxy (MBE) method, and a laser transfer method. Examples of the CVD method include a plasma CVD method, a thermal CVD method, an organic metal (MO) CVD method, and a photo-CVD method. Furthermore, examples of other methods include: an electroplating method, an electroless plating method, or a spin coating method; a dipping method; a cast method; a micro-contact printing; a drop cast method; various printing methods such as a screen printing method, an inkjet printing method, an offset printing method, a gravure printing method, and a flexographic printing method; a stamping method; a spray method; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calender coater method. Furthermore, examples of the patterning method include chemical etching such as shadow masking, laser transfer, or photolithography and physical etching using ultraviolet rays, laser, or the like. In addition, examples of the planarization technology include a CMP method, a laser planarization method, and a reflow method.

### 4. APPLICATION EXAMPLES

### 4.1 Application Example to Camera

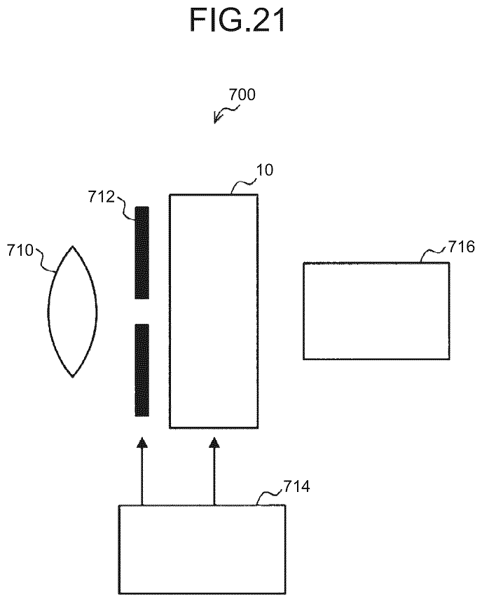

The technology according to the present disclosure (present technology) can be applied to various products. For example, the technology according to the present disclosure may be applied to a camera or the like. Therefore, a configuration example of a camera 700 as an electronic device to which the present technology is applied will be described with reference to FIG. 21. FIG. 21 is an explanatory diagram illustrating an example of a schematic functional configuration of the camera 700 to which the technology according to the present disclosure (present technology) can be applied.

As illustrated in FIG. 21, the camera 700 includes an imaging device 10, an optical lens 710, a shutter mechanism 712, a drive circuit unit 714, and a signal processing circuit unit 716. The optical lens 710 forms an image of image light (incident light) from a subject on an imaging surface of the imaging device 10. As a result, signal charges are accumulated in an imaging element 300 of the imaging device 10 for a certain period of time. The shutter mechanism 712 opens and closes to control a light exposure period and a light shielding period for the imaging device 10. The drive circuit unit 714 supplies a drive signal for controlling a signal transfer operation of the imaging device 10, a shutter operation of the shutter mechanism 712, and the like to these units. That is, the imaging device 10 performs signal transfer on the basis of the drive signal (timing signal) supplied from the drive circuit unit 714. The signal processing circuit unit 716 performs various types of signal processing. For example, the signal processing circuit unit 716 outputs a video signal subjected to the signal processing to, for example, a storage medium (not illustrated) such as a memory or to a display unit (not illustrated).

The configuration example of the camera 700 has been described above. Each of the above components may be configured using a general-purpose member or may be configured by hardware specialized in the function of the component. Such a configuration can be modified as appropriate depending on the technical level at the time of implementation.

### <4.2 Application Example to Smartphone>

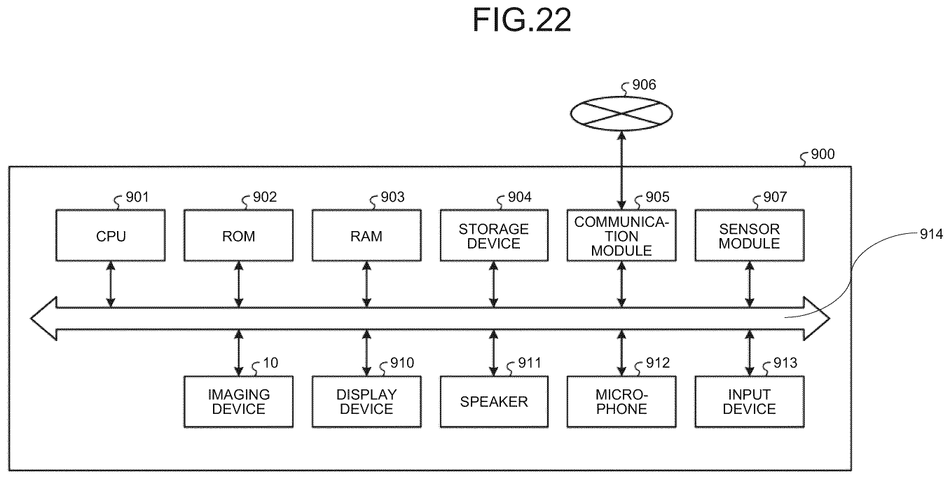

For example, the technology according to the present disclosure may be applied to a smartphone or the like. Therefore, a configuration example of a smartphone 900 as an electronic device to which the present technology is applied will be described with reference to FIG. 22. FIG. 22 is a block diagram illustrating an example of a schematic functional configuration of the smartphone 900 to which the technology according to the present disclosure (present technology) can be applied.

As illustrated in FIG. 22, the smartphone 900 includes a central processing unit (CPU) 901, a read only memory (ROM) 902, and a random access memory (RAM) 903. The smartphone 900 further includes a storage device 904, a communication module 905, and a sensor module 907. Furthermore, the smartphone 900 includes an imaging device 10, a display device 910, a speaker 911, a microphone 912, an input device 913, and a bus 914. Furthermore, the smartphone 900 may include a processing circuit such as a digital signal processor (DSP) instead of or in addition to the CPU 901.

The CPU 901 functions as an arithmetic processing device and a control device and controls the overall operation in the smartphone 900 or a part thereof in accordance with various programs recorded in the ROM 902, the RAM 903, the storage device 904, or the like. The ROM 902 stores programs, operation parameters, and the like used by the CPU 901. The RAM 903 primarily stores programs used in execution by the CPU 901, parameters that vary as appropriate in the execution, and the like. The CPU 901, the ROM 902, and the RAM 903 are connected to each other by the bus 914. In addition, the storage device 904 is a device for data storage configured as an example of a storage unit of the smartphone 900. The storage device 904 includes, for example, a magnetic storage device such as a hard disk drive (HDD), a semiconductor storage device, an optical storage device, and the like. The storage device 904 stores programs and various types of data executed by the CPU 901, various types of data acquired from the outside, and the like.

The communication module 905 is a communication interface including, for example, a communication device for connecting to a communication network 906. The communication module 905 can be, for example, a communication card for wired or wireless local area network (LAN), Bluetooth (registered trademark), wireless USB (WUSB) or the like. Furthermore, the communication module 905 may be a router for optical communication, a router for asymmetric digital subscriber line (ADSL), a modem for various types of communication, or the like. The communication module 905 transmits and receives signals and the like to and from the Internet or other communication devices using a predetermined protocol such as Transmission Control Protocol (TCP)/Internet Protocol (IP). Furthermore, the communication network 906 connected to the communication module 905 is a network connected in a wired or wireless manner and is, for example, the Internet, a home LAN, infrared communication, satellite communication, or the like.

The sensor module 907 includes various sensors such as

a motion sensor (for example, an acceleration sensor, a gyro sensor, a geomagnetic sensor, or the like), a biological information sensor (for example, a pulse sensor, a blood pressure sensor, a fingerprint sensor, and the like), or a position sensor (for example, a global navigation satellite system (GNSS) receiver or the like).

The imaging device 10 is provided on a surface of the smartphone 900 and can capture an image of an object or the like located on the back side or the front side of the smartphone 900. Specifically, the technology according to the present disclosure (the present technology) can be applied to the imaging device 10. Furthermore, the imaging device 10 can further include an optical system mechanism (not illustrated) including an imaging lens, a zoom lens, a focus lens, and the like and a drive system mechanism (not illustrated) that controls the operation of the optical system mechanism. Then, the imaging device 10 can collect incident light from an object as an optical image, photoelectrically convert the formed optical image for every 300 imaging elements (pixels), read a signal obtained by the conversion as an imaging signal, and perform image processing to acquire a captured image.

The display device 910 is provided on a surface of the smartphone 900 and can be a display device such as a liquid crystal display (LCD) or an organic electro luminescence (EL) display. The display device 910 can display an operation screen, a captured image acquired by the above-described imaging device 10, and others.

The speaker 911 can output, for example, a call voice, a voice accompanying the video content displayed by the display device 910 described above, and the like to a user.

The microphone 912 can collect, for example, a call voice of the user, a voice including a command to activate a function of the smartphone 900, and a voice in a surrounding environment of the smartphone 900.

The input device 913 is a device operated by the user, such as a button, a keyboard, a touch panel, or a mouse. The input device 913 includes an input control circuit that generates an input signal on the basis of information input by the user and outputs the input signal to the CPU 901. By operating the input device 913, the user can input various types of data to the smartphone 900 or give an instruction on a processing operation.

The configuration example of the smartphone 900 has been described above. Each of the above components may be configured using a general-purpose member or may be configured by hardware specialized in the function of the component. Such a configuration can be modified as appropriate depending on the technical level at the time of implementation.

### <4.3 Application Example to Mobile Device Control System>

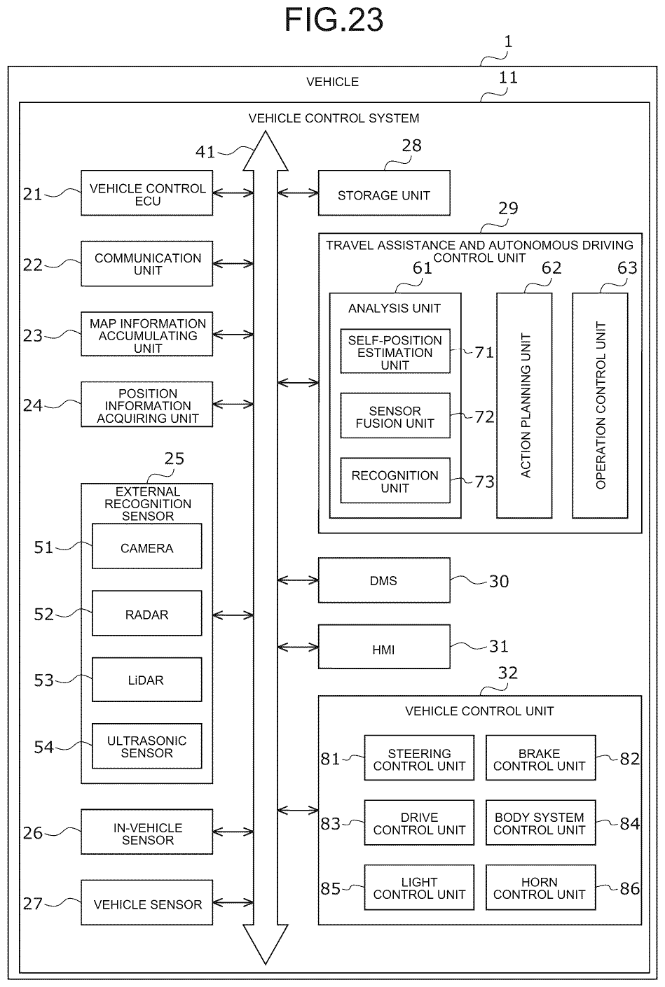

For example, the technology according to the present disclosure may be applied to a mobile device control system or the like. Therefore, an example of a mobile device control system to which the technology proposed in the present disclosure can be applied will be described with reference to FIG. 23. FIG. 23 is a block diagram illustrating a configuration example of a vehicle control system 11 as an example of a traveling device control system to which the present technology is applied.

The vehicle control system 11 is included in a vehicle 1 and performs processing related to travel assistance and autonomous driving of the vehicle 1.

The vehicle control system 11 includes a vehicle control electronic control unit (ECU) 21, a communication unit 22, a map information accumulating unit 23, a position information acquiring unit 24, an external recognition sensor 25, an in-vehicle sensor 26, a vehicle sensor 27, a storage unit 28, a travel assistance and autonomous driving control unit 29, a driver monitoring system (DMS) 30, a human-machine interface (HMI) 31, and a vehicle control unit 32.

The vehicle control ECU 21, the communication unit 22, the map information accumulating unit 23, the position information acquiring unit 24, the external recognition sensor 25, the in-vehicle sensor 26, the vehicle sensor 27, the storage unit 28, the travel assistance and autonomous driving control unit 29, the driver monitoring system (DMS) 30, the human-machine interface (HMI) 31, and the vehicle control unit 32 are communicably connected to each other via a communication network 41. The communication network 41 includes, for example, an in-vehicle communication network conforming to digital bilateral communication standards, such as a controller area network (CAN), a local interconnect network (LIN), a local area network (LAN), FlexRay (registered trademark), or Ethernet (registered trademark), a bus, or the like. The communication network 41 may be selectively used depending on the type of data to be transmitted. For example, a CAN may be applied to data related to vehicle control, and Ethernet may be applied to large-capacity data. Note that each unit of the vehicle control system 11 may be directly connected, not via the communication network 41, but by using wireless communication based on the premise of communication at a relatively short distance, such as near field communication (NFC) or Bluetooth (registered trademark). Note that, hereinafter, in a case where each unit of the vehicle control system 11 performs communication via the communication network 41, description of the communication network 41 will be omitted. For example, in a case where the vehicle control ECU 21 and the communication unit 22 perform communication via the communication network 41, it is simply described that the vehicle control ECU 21 and the communication unit 22 perform communication.

The vehicle control ECU 21 includes, for example, various processors such as a central processing unit (CPU) or a micro processing unit (MPU). The vehicle control ECU 21 can control all or some of functions of the vehicle control system 11.

The communication unit 22 can communicate with various devices inside and outside the vehicle, other vehicles, servers, base stations, and the like and transmit and receive various types of data. At this point, the communication unit 22 may perform communication using a plurality of communication schemes.

Communication that the communication unit 22 can execute with the outside of the vehicle will be schematically described below. The communication unit 22 can communicate with a server (hereinafter, referred to as an external server) or the like on an external network via a base station or an access point by a wireless communication scheme such as the 5th generation mobile communication system (5G), long term evolution (LTE), or dedicated short range communications (DSRC). The external network with which the communication unit 22 communicates is, for example, the Internet, a cloud network, a network unique to a company, or the like. The communication scheme performed by the communication unit 22 with the external network is not particularly limited as long as it is a wireless communication scheme capable of performing digital bidirectional communication at a communication speed equal to or higher than a predetermined speed and at a distance equal to or longer than a predetermined distance.

Furthermore, for example, the communication unit 22 can communicate with a terminal present in the vicinity of the host vehicle using the peer to peer (P2P) technology. Examples of the terminal present in the vicinity of the host vehicle include a terminal worn by a traveling body traveling at a relatively low speed such as a pedestrian or a bicycle, a terminal installed in a store or the like with a position fixed, or a machine type communication (MTC) terminal. Furthermore, the communication unit 22 can also perform V2X communication. The V2X communication refers to communication between the host vehicle and another party, such as vehicle to vehicle communication with another vehicle, vehicle to infrastructure communication with a roadside device or the like, vehicle to home communication with a house, and vehicle to pedestrian communication with a terminal or the like carried by a pedestrian.

The communication unit 22 can receive, for example, a program for updating software for controlling the operation of the vehicle control system 11 from the outside (Over-the-Air). The communication unit 22 can further receive map information, traffic information, information of the surroundings of the vehicle 1, and others from the outside. Furthermore, for example, the communication unit 22 can transmit information regarding the vehicle 1, information of the surroundings of the vehicle 1, and others to the outside. Examples of the information of the vehicle 1 transmitted to the outside by the communication unit 22 include data indicating the state of the vehicle 1, a recognition result by a recognition unit 73, and others. Furthermore, for example, the communication unit 22 can perform communication conforming to a vehicle emergency call system such as the eCall.

For example, the communication unit 22 can receive an electromagnetic wave transmitted by the vehicle information and communication system (VICS) (registered trademark) such as a radio wave beacon, an optical beacon, or FM multiplex broadcasting.

Communication that the communication unit 22 can execute with the inside of the vehicle will be also schematically described. The communication unit 22 can communicate with each device in the vehicle using, for example, wireless communication. The communication unit 22 can perform wireless communication with an in-vehicle device by a communication scheme capable of performing digital bidirectional communication at a communication speed equal to or higher than a predetermined speed by wireless communication, such as wireless LAN, Bluetooth (registered trademark), NFC, or wireless USB (WUSB). Without being limited to the above, the communication unit 22 can also communicate with each device in the vehicle using wired communication. For example, the communication unit 22 can communicate with each device in the vehicle by wired communication via a cable connected to a connection terminal (not illustrated). The communication unit 22 can communicate with each device in the vehicle by a communication scheme capable of performing digital bidirectional communication at a predetermined communication speed or higher by wired communication, such as the universal serial bus (USB), high-definition multimedia interface (HDMI) (registered trademark), or mobile high-definition link (MHL).

Here, a device in the vehicle refers to, for example, a device that is not connected to the communication network 41 in the vehicle. As examples of the device in the vehicle, a mobile device or a wearable device carried by a passenger such as a driver, an information device brought into the vehicle and temporarily installed, or the like are conceivable.

The map information accumulating unit 23 can accumulate one or both of a map acquired from the outside and a map created in the vehicle 1. For example, the map information accumulating unit 23 accumulates three-dimensional high-precision maps, a global map having lower accuracy than the high-precision maps but covering a wide area, and others.

The high-precision maps are, for example, dynamic maps, point cloud maps, vector maps, or others. The dynamic map is, for example, a map including four layers of dynamic information, semi-dynamic information, semi-static information, and static information and is provided to the vehicle 1 from an external server or the like. The point cloud map is a map including point clouds (point cloud data). The vector map is, for example, a map in which traffic information such as lanes and positions of traffic lights are associated with a point cloud map and adapted to an advanced driver assistance system (ADAS) or autonomous driving (AD).

The point cloud map and the vector map may be provided from, for example, an external server or the like or may be created in the vehicle 1 as a map for performing matching with a local map to be described later on the basis of a sensing result by a camera 51, a radar 52, a LiDAR 53, or the like and accumulated in the map information accumulating unit 23. In addition, in a case where a high-precision map is provided from an external server or the like, for example, map data of several hundred meters square regarding a planned path on which the vehicle 1 is about to travel is acquired from an external server or the like in order to reduce the communication capacity. The position information acquiring unit 24 can receive global navigation satellite system (GNSS) signals from GNSS satellites and acquire position information of the vehicle 1. The acquired position information is supplied to the travel assistance and autonomous driving control unit 29. Note that the position information acquiring unit 24 is not limited to the method using the GNSS signals and may acquire the position information using, for example, a beacon.

The external recognition sensor 25 includes various sensors used for recognition of a situation outside the vehicle 1 and can supply sensor data from each sensor to each unit of the vehicle control system 11. The type and number of sensors included in the external recognition sensor 25 are not particularly limited.

The external recognition sensor 25 includes, for example, the camera 51, the radar 52, the light detection and ranging (laser imaging detection and ranging) (LiDAR) 53, and an ultrasonic sensor 54. Without being limited thereto, the external recognition sensor 25 may include one or more types of sensors of the camera 51, the radar 52, the LiDAR 53, and the ultrasonic sensor 54. The numbers of cameras 51, radars 52, LiDARs 53, and ultrasonic sensors 54 are not particularly limited as long as they can be practically installed in the vehicle 1. Furthermore, the types of sensors included in the external recognition sensor 25 is not limited to this example, and the external recognition sensor 25 may include other types of sensors. An example of the sensing area of each sensor included in the external recognition sensor 25 will be described later.

Note that the imaging method of the camera 51 is not particularly limited. For example, cameras of various imaging methods such as a time-of-flight (ToF) camera, a stereo camera, a monocular camera, and an infrared camera of imaging methods capable of ranging can be applied to the camera 51, as necessary. Moreover, the camera 51 may simply acquire a captured image regardless of ranging. Furthermore, the imaging device 10 according to the embodiment of the present disclosure can be applied to the camera 51.

Furthermore, for example, the external recognition sensor 25 can include an environment sensor for detecting the environment for the vehicle 1. The environment sensor is a sensor for detecting an environment such as the weather, the climate, or the brightness and can include various sensors such as a raindrop sensor, a fog sensor, a sunshine sensor, a snow sensor, and an illuminance sensor.

Furthermore, for example, the external recognition sensor 25 includes a microphone used for detection of sound around the vehicle 1, a position of a sound source, and the like.

The in-vehicle sensor 26 includes various sensors for detecting information inside the vehicle and can supply sensor data from the sensors to respective units of the vehicle control system 11. The type and the number of various sensors included in the in-vehicle sensor 26 are not particularly limited as long as they can be practically installed in the vehicle 1.

For example, the in-vehicle sensor 26 can include one or more types of sensors of a camera, a radar, a seating sensor, a steering wheel sensor, a microphone, and a biological sensor. As the camera included in the in-vehicle sensor 26, for example, cameras of various imaging methods capable of ranging, such as a ToF camera, a stereo camera, a monocular camera, and an infrared camera, can be used. Without being limited to the above, the camera included in the in-vehicle sensor 26 may simply acquire a captured image regardless of ranging. The imaging device 10 according to the embodiment of the present disclosure can also be applied to the camera included in the in-vehicle sensor 26. The biological sensor included in the in-vehicle sensor 26 is included, for example, in a seat, a steering wheel, or the like and detects various types of biological information of a passenger such as the driver.

The vehicle sensor 27 includes various sensors for detecting the state of the vehicle 1 and supplies sensor data from the sensors to respective units of the vehicle control system 11. The type and the number of various sensors included in the vehicle sensor 27 are not particularly limited as long as they can be practically installed in the vehicle 1.

For example, the vehicle sensor 27 can include a speed sensor, an acceleration sensor, an angular velocity sensor (gyro sensor), and an inertial measurement unit (IMU) integrating these sensors. For example, the vehicle sensor 27 includes a steering angle sensor that detects the steering angle of the steering wheel, a yaw rate sensor, an accelerator sensor that detects an operation amount of the accelerator pedal, and a brake sensor that detects an operation amount of the brake pedal. For example, the vehicle sensor 27 includes a rotation sensor that detects the number of revolutions of the engine or the motor, an air pressure sensor that detects the air pressure of the tires, a slip rate sensor that detects the slip rate of the tires, and a wheel speed sensor that detects the rotation speed of the wheels. For example, the vehicle sensor 27 includes a battery sensor that detects the remaining amount and the temperature of the battery and an impact sensor that detects an external impact.

The storage unit 28 includes at least one of a nonvolatile storage medium or a volatile storage medium and can store data or a program. The storage unit 28 is used as, for example, an electrically erasable programmable read-only memory (EEPROM) and a random access memory (RAM), and a magnetic storage device such as a hard disc drive (HDD), a semiconductor storage device, an optical storage device, and a magneto-optical storage device can be applied as the storage medium. The storage unit 28 stores various programs and data used by each unit of the vehicle control system 11. For example, the storage unit 28 includes an event data recorder (EDR) or a data storage system for automated driving (DSSAD) and stores information of the vehicle 1 before and after an event such as an accident or information acquired by the in-vehicle sensor 26.

The travel assistance and autonomous driving control unit 29 can control travel assistance and autonomous driving of the vehicle 1. For example, the travel assistance and autonomous driving control unit 29 includes an analysis unit 61, an action planning unit 62, and an operation control unit 63.

The analysis unit 61 can perform analysis processing of the situation of the vehicle 1 and the surroundings. The analysis unit 61 includes a self-position estimation unit 71, a sensor fusion unit 72, and the recognition unit 73.

The self-position estimation unit 71 can estimate the self-position of the vehicle 1 on the basis of the sensor data from the external recognition sensor 25 and the high-precision maps accumulated in the map information accumulating unit 23. For example, the self-position estimation unit 71 generates a local map on the basis of the sensor data from the external recognition sensor 25 and estimates the self-position of the vehicle 1 by matching the local map with the high-precision maps. The position of the vehicle 1 can be based on, for example, the center of the axle of the pair of rear wheels.

The local map is, for example, a three-dimensional high-precision map created using technology such as simultaneous localization and mapping (SLAM), an occupancy grid map, or the like. The three-dimensional high-precision map is, for example, the above-described point cloud map or the like. The occupancy grid map is a map in which a three-dimensional or two-dimensional space around the vehicle 1 is divided into grids of a predetermined size, and an occupancy state of an object is indicated for every grid. The occupancy state of the object is indicated by, for example, the presence or absence or the presence probability of the object. The local map is also used for detection processing and recognition processing of a situation outside the vehicle 1 by the recognition unit 73, for example.

Note that the self-position estimation unit 71 may estimate the self-position of the vehicle 1 on the basis of the position information acquired by the position information acquiring unit 24 and the sensor data from the vehicle sensor 27.

The sensor fusion unit 72 can perform sensor fusion processing of combining a plurality of different types of sensor data (for example, image data supplied from the camera 51 and sensor data supplied from the radar 52) to obtain new information. Those conceivable as methods for combining different types of sensor data are integration, fusion, association, and the like.

The recognition unit 73 can execute detection processing for detecting a situation outside the vehicle 1 and recognition processing for recognizing the situation outside the vehicle 1.

For example, the recognition unit 73 performs detection processing and recognition processing of the situation outside the vehicle 1 on the basis of information from the external recognition sensor 25, information from the self-position estimation unit 71, information from the sensor fusion unit 72, and others.

Specifically, for example, the recognition unit 73 performs detection processing, recognition processing, and the like of an object around the vehicle 1. The detection processing of an object is, for example, processing of detecting the presence or absence, the size, the shape, the position, the motion, and the like of the object. The recognition processing of an object is, for example, processing of recognizing an attribute such as the type of the object or identifying a specific object. However, the detection processing and the recognition processing are not necessarily clearly divided and may overlap with each other.

For example, the recognition unit 73 detects an object around the vehicle 1 by performing clustering of classifying point clouds based on sensor data by the radar 52, the LiDAR 53, or the like into groups of point clouds. As a result, the presence or absence, the size, the shape, and the position of an object around the vehicle 1 are detected.

For example, the recognition unit 73 detects the motion of an object around the vehicle 1 by performing tracking of following the motion of a group of point clouds classified by the clustering. As a result, the speed and the traveling direction (travel vector) of the object around the vehicle 1 are detected.

For example, the recognition unit 73 detects or recognizes a vehicle, a person, a bicycle, an obstacle, a structure, a road, a traffic light, a traffic sign, road marking, and the like on the basis of image data supplied from the camera 51. Furthermore, the recognition unit 73 may recognize the type of the object around the vehicle 1 by performing recognition processing such as semantic segmentation. For example, the recognition unit 73 can perform recognition processing of traffic rules around the vehicle 1 on the basis of the maps accumulated in the map information accumulating unit 23, an estimation result of the self-position by the self-position estimation unit 71, and a recognition result of the object around the vehicle 1 by the recognition unit 73. Through this processing, the recognition unit 73 can recognize the position and the state of the traffic light, the content of the traffic sign and the road marking, the content of the traffic regulations, travelable lanes, and the like.

For example, the recognition unit 73 can perform the recognition processing of the environment around the vehicle 1. As the surrounding environment to be recognized by the recognition unit 73, the weather, the temperature, the humidity, the brightness, the state of a road surface, and the like are conceivable.

The action planning unit 62 creates an action plan of the vehicle 1. For example, the action planning unit 62 can create an action plan by performing processing of global path planning and path tracking.

Note that the global path planning is processing of planning a rough path from the start to the goal. This global path planning also includes processing, referred to as path planning, of performing local path planning that enables safe and smooth traveling in the vicinity of the vehicle 1 in consideration of the motion characteristics of the vehicle 1 on the planned path.

The path tracking is processing of planning an operation for safely and accurately traveling on the path planned by the global path planning within a planned time. For example, the action planning unit 62 can calculate a target speed and a target angular velocity of the vehicle 1 on the basis of the result of the path tracking processing.

The operation control unit 63 can control the operation of the vehicle 1 in order to implement the action plan created by the action planning unit 62.

For example, the operation control unit 63 controls a steering control unit 81, a brake control unit 82, and a drive control unit 83 included in the vehicle control unit 32, to be described later, to perform acceleration and deceleration control and direction control in such a manner that the vehicle 1 travels on the path calculated by the path planning. For example, the operation control unit 63 performs cooperative control for the purpose of implementing the functions of the ADAS such as collision avoidance or impact mitigation, follow-up traveling, vehicle speed maintaining traveling, collision warning for the host vehicle, lane deviation warning for the host vehicle, and the like. The operation control unit 63 performs, for example, cooperative control intended for autonomous driving or the like in which the vehicle travels autonomously without depending on the operation of the driver.

The DMS 30 can perform authentication processing of the driver, recognition processing of the state of the driver, and the like on the basis of sensor data from the in-vehicle sensor 26, input data input to the HMI 31 to be described later, and others. As the state of the driver to be recognized, for example, the physical condition, the arousal level, the concentration level, the fatigue level, the line-of-sight direction, the drunkenness level, a driving operation, the posture, and the like are conceivable.

Note that the DMS 30 may perform authentication processing of a passenger other than the driver and recognition processing of the state of the passenger. Furthermore, for example, the DMS 30 may perform recognition processing of the situation inside the vehicle on the basis of the sensor data from the in-vehicle sensor 26. As the situation inside the vehicle to be recognized, for example, the temperature, the humidity, the brightness, the odor or the sent, and the like are conceivable.

The HMI 31 can input various types of data, instructions, and the like and present various types of data to the driver and others.

Data input by the HMI 31 will be schematically described. The HMI 31 has an input device for a person to input data. The HMI 31 generates an input signal on the basis of data, an instruction, or the like input by the input device and supplies the input signal to each unit of the vehicle control system 11. The HMI 31 includes an operator such as a touch panel, a button, a switch, or a lever as the input device. Without being limited thereto, the HMI 31 may further include an input device capable of inputting information by a method other than manual operation such as by voice, a gesture, or others. Furthermore, the HMI 31 may use, for example, a remote control device using infrared rays or radio waves or an external connection device such as a mobile device or a wearable device supporting the operation of the vehicle control system 11 as the input device.

Presentation of data by the HMI 31 will be schematically described. The HMI 31 generates visual information, auditory information, and tactile information for the passengers or the outside of the vehicle. In addition, the HMI 31 performs output control for controlling output, output content, output timing, an output method, and others of each piece of information that is generated. The HMI 31 generates and outputs, as the visual information, information indicated by images or light such as an operation screen, state display of the vehicle 1, warning display, or a monitor image indicating a situation around the vehicle 1. Furthermore, the HMI 31 generates and outputs information indicated by sound such as a voice guidance, a warning sound, or a warning message as the auditory information. Furthermore, the HMI 31 generates and outputs, as the tactile information, information given to the tactile sense of the passenger by, for example, a force, vibrations, a motion, or the like.

As an output device with which the HMI 31 outputs the visual information, for example, a display device that presents the visual information by displaying an image thereon or a projector device that presents the visual information by projecting an image are applicable. Note that the display device may be a device that displays the visual information in the field of view of the passenger such as a head-up display, a transmissive display, or a wearable device having an augmented reality (AR) function other than a display device having a normal display. In addition, the HMI 31 can use display devices included in a navigation device, an instrument panel, a camera monitoring system (CMS), an electronic mirror, a lamp, or the like included in the vehicle 1 as an output device that outputs the visual information.

As an output device from which the HMI 31 outputs the auditory information, for example, an audio speaker, headphones, or earphones are applicable.

As an output device to which the HMI 31 outputs the tactile information, for example, a haptics element using haptic technology is applicable. The haptics element is provided, for example, at a portion with which a passenger of the vehicle 1 comes into contact, such as a steering wheel or a seat.

The vehicle control unit 32 can control each unit of the vehicle 1. The vehicle control unit 32 includes the steering control unit 81, a brake control unit 82, the drive control unit 83, a body system control unit 84, a light control unit 85, and a horn control unit 86.

The steering control unit 81 can detect and control the state of the steering system of the vehicle 1. The steering system includes, for example, a steering mechanism including a steering wheel and the like, an electric power steering, and the like. The steering control unit 81 includes, for example, a steering ECU that controls the steering system, an actuator that drives the steering system, and others.

The brake control unit 82 can detect and control the state of the brake system of the vehicle 1. The brake system includes, for example, a brake mechanism including a brake pedal and the like, an antilock brake system (ABS), a regenerative brake mechanism, and the like. The brake control unit 82 includes, for example, a brake ECU that controls the brake system, an actuator that drives the brake system, and the like.

The drive control unit 83 can detect and control the state of a drive system of the vehicle 1. The drive system includes, for example, a driving force generation device for generating a driving force such as an accelerator pedal, an internal combustion engine, and a driving motor, a driving force transmission mechanism for transmitting the driving force to wheels, and others. The drive control unit 83 includes, for example, a drive ECU that controls the drive system, actuators that drive the drive system, and others.

The body system control unit 84 can detect and control the state of a body system of the vehicle 1. The body system includes, for example, a keyless entry system, a smart key system, a power window device, a power seat, an air conditioner, an airbag, a seat belt, a shift lever, and others. The body system control unit 84 includes, for example, a body system ECU that controls the body system, actuators that drive the body system, and others.

The light control unit 85 can detect and control states of various lights of the vehicle 1. As the lights to be controlled, for example, a headlight, a backlight, a fog light, a turn signal, a brake light, projection, display on a bumper, and the like are conceivable. The light control unit 85 includes a light ECU that controls the lights, actuators that drive the lights, and the like.

The horn control unit 86 can detect and control the state of a car horn of the vehicle 1. The horn control unit 86 includes, for example, a horn ECU that controls the car horn, an actuator that drives the car horn, and the like.

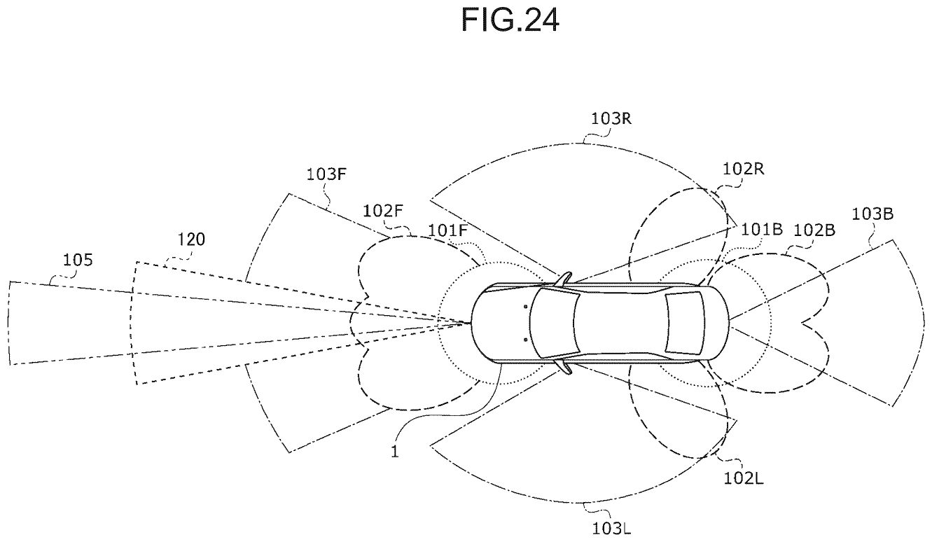

FIG. 24 is a diagram illustrating an example of sensing areas by the camera 51, the radar 52, the LiDAR 53, the ultrasonic sensor 54, or others of the external recognition sensor 25 in FIG. 23. Note that FIG. 24 schematically illustrates the vehicle 1 as viewed from above, in which the left end side is the front end (front) side of the vehicle 1, and the right end side is the rear end (rear) side of the vehicle 1.

A sensing area 101F and a sensing area 101B indicate examples of sensing areas of ultrasonic sensors 54. The sensing area 101F covers the periphery of the front end of the vehicle 1 by a plurality of ultrasonic sensors 54. The sensing area 101B covers the periphery of the rear end of the vehicle 1 by a plurality of ultrasonic sensors 54.

Sensing results in the sensing area 101F and the sensing area 101B are used for, for example, parking assistance or the like of the vehicle 1.

A sensing area 102F or a sensing area 102B indicates an example of a sensing area of the radar 52 for a short distance or a middle distance. The sensing area 102F covers up to a position farther than the sensing area 101F ahead of the vehicle 1. The sensing area 102B covers up to a position farther than the sensing area 101B behind the vehicle 1. A sensing area 102L covers the rear periphery of the left side face of the vehicle 1. A sensing area 102R covers the rear periphery of the right side face of the vehicle 1.

A sensing result in the sensing area 102F is used for, for example, detecting a vehicle, a pedestrian, or the like present ahead of the vehicle 1. A sensing result in the sensing area 102B is used for, for example, a collision prevention function or the like behind the vehicle 1. Sensing results in the sensing area 102L and the sensing area 102R are used for, for example, detecting an object in a blind spot on the sides of the vehicle 1.

A sensing area 103F or a sensing area 103B indicates an example of a sensing area by the camera 51. The sensing area 103F covers up to a position farther than the sensing area 102F ahead of the vehicle 1. The sensing area 103B covers up to a position farther than the sensing area 102B behind the vehicle 1. A sensing area 103L covers the periphery of the left side face of the vehicle 1. A sensing area 103R covers the periphery of the right side face of the vehicle 1.

A sensing result in the sensing area 103F can be used for, for example, recognition of a traffic light or a traffic sign, a lane deviation prevention assist system, and an automatic headlight control system. A sensing result in the sensing area 103B can be used for, for example, parking assistance and a surround view system. Sensing results in the sensing area 103L and the sensing area 103R can be used for the surround view system, for example.

A sensing area 120 indicates an example of a sensing area of the LiDAR 53. The sensing area 120 covers up to a position farther than the sensing area 103F ahead of the vehicle 1. Meanwhile, the sensing area 120 has a narrower area in the left-right direction than that of the sensing area 103F.

A sensing result in the sensing area 120 is used for, for example, detecting an object such as a surrounding vehicle.

A sensing area 105 indicates an example of a sensing area of the radar 52 for a long distance. The sensing area 105 covers up to a position farther than the sensing area 120 ahead of the vehicle 1. Meanwhile, the sensing area 105 has a narrower area in the left-right direction than that of the sensing area 120.

A sensing result in the sensing area 105 is used for, for example, adaptive cruise control (ACC), emergency braking, collision avoidance, and the like.

Note that the sensing areas of the sensors of the camera 51, the radar 52, the LiDAR 53, and the ultrasonic sensor 54 included in the external recognition sensor 25 may have various configurations other than those in FIG. 24. Specifically, the ultrasonic sensor 54 may also perform sensing on the sides of the vehicle 1, or the LiDAR 53 may perform sensing behind the vehicle 1. In addition, the installation positions of the sensors are not limited to the examples described above. Furthermore, the number of the sensors may be one or plural.

### 5. SUPPLEMENTS

Although the preferred embodiment of the disclosure have been described in detail by referring to the accompanying drawings, the technical scope of the disclosure is not limited to such examples. It is obvious that a person having ordinary knowledge in the technical field of the present disclosure can conceive various modifications or variations within the scope of the technical idea described in the claims, and it is naturally understood that these also belong to the technical scope of the present disclosure.

Incidentally, the effects described in the present specification are merely illustrative or exemplary and are not limiting. That is, the technology according to the present disclosure can achieve other effects that are obvious to those skilled in the art from the description of the present specification together with or in place of the above effects.

Note that the present technology can also have the following structures.

(1) A semiconductor device comprising a stack of a first semiconductor substrate and a second semiconductor substrate, wherein
the first semiconductor substrate includes:
an imaging element that generates a charge in response to light from a light incident surface of the first semiconductor substrate; and
a first memory element provided on a side opposite to the light incident surface with respect to the imaging element, and
the first memory element
has a stacked structure in which a magnetization fixed layer, a nonmagnetic layer, and a storage layer are stacked in the order mentioned from the light incident surface side.
   (2) The semiconductor device according to (1), wherein
a cross section of the first memory element cut along a stacking direction has a trapezoidal shape, and
a length of an upper base located on the light incident surface side of the trapezoid is longer than a length of a lower base of the trapezoid.
   (3) The semiconductor device according to (1) or (2), wherein the second semiconductor substrate includes a logic circuit.
   (4) The semiconductor device according to any one of (1) to (3), wherein the first semiconductor substrate and the second semiconductor substrate are joined to each other by junction electrodes provided to the first semiconductor substrate and the second semiconductor substrate.
   (5) The semiconductor device according to (4), wherein the junction electrodes are formed of copper.
   (6) The semiconductor device according to any one of (1) to (5), wherein
the first memory element further includes
a first electrode and a second electrode sandwiching the stacked structure,
the first electrode is located on the light incident surface side with respect to the stacked structure, and
the second electrode is electrically connected with a selection transistor.
   (7) The semiconductor device according to (6), wherein the selection transistor is an n-type MOS transistor.
   (8) The semiconductor device according to any one of (1) to (7), wherein
the first memory element is electrically connected to a read transistor and a write transistor, and
film thicknesses of gate oxide films of the read transistor and the write transistor are different from each other.
   (9) The semiconductor device according to any one of (1) to (8), wherein
the first semiconductor substrate includes:
a pixel region including a plurality of the imaging elements arrayed two-dimensionally; and
a memory area including a plurality of the first memory elements arrayed two-dimensionally.
   (10) The semiconductor device according to (9), wherein at least some of the plurality of first memory elements are volatile storage elements.
   (11) The semiconductor device according to (9), wherein at least some of the plurality of first memory elements are nonvolatile storage elements.
   (12) The semiconductor device according to (9), wherein the plurality of first memory elements includes a volatile storage element and a nonvolatile storage element.
   (13) The semiconductor device according to (11) or (12), wherein the nonvolatile storage element includes an OTP storage element in which the nonmagnetic layer is destroyed.
   (14) The semiconductor device according to any one of (9) to (13), wherein the memory area includes a logic circuit.
   (15) The semiconductor device according to any one of (1) to (14), wherein the second semiconductor substrate does not include a memory element.
   (16) The semiconductor device according to any one of (9) to (14), wherein the second semiconductor substrate includes a plurality of second memory elements.
   (17) The semiconductor device according to (16), wherein
each of the second memory elements
has a stacked structure in which a storage layer, a nonmagnetic layer, and a magnetization fixed layer are stacked in the order mentioned from the first semiconductor substrate side.
   (18) The semiconductor device according to (16) or (17), wherein each of the first memory elements and each of the second memory elements are connected in series.
   (19) The semiconductor device according to (18), further comprising
a plurality of memory element pairs each including one of the first memory elements and one of the second memory elements connected in series, wherein
individual resistance values of the plurality of memory element pairs are different from each other.
   (20) An electronic device mounted with a semiconductor device, the semiconductor device including a stack of a first semiconductor substrate and a second semiconductor substrate, wherein
the first semiconductor substrate includes:
an imaging element that generates a charge in response to light from a light incident surface of the first semiconductor substrate; and
a first memory element provided on a side opposite to the light incident surface with respect to the imaging element, and
the first memory element
has a stacked structure in which a magnetization fixed layer, a nonmagnetic layer, and a storage layer are stacked in the order mentioned from the light incident surface side.

### REFERENCE SIGNS LIST

10, 10a IMAGING DEVICE
100, 100a FIRST SEMICONDUCTOR SUBSTRATE
102, 202 FRONT SURFACE
104, 204 BACK SURFACE
110, 210 CONNECTING PORTION
200, 200a SECOND SEMICONDUCTOR SUBSTRATE
300 IMAGING ELEMENT
400, 400a, 400b MTJ ELEMENT
402 FIXED LAYER
404 NONMAGNETIC LAYER
406 STORAGE LAYER
420, 420a SELECTION TRANSISTOR
500 INSULATING FILM
502 LOWER WIRING
504 DAMASCENE STRUCTURE
506 BARRIER METAL FILM
508, 512 ELECTRODE
510 MIJ LAYER
514 HARDMASK
516 PROTECTIVE FILM
518 INTERLAYER INSULATING FILM
520 WIRING
700 CAMERA
710 OPTICAL LENS
712 SHUTTER MECHANISM
714 DRIVE CIRCUIT UNIT
716 SIGNAL PROCESSING CIRCUIT UNIT
900 SMARTPHONE
901 CPU
902 ROM
903 RAM
904 STORAGE DEVICE
905 COMMUNICATION MODULE
906 COMMUNICATION NETWORK
907 SENSOR MODULE
910 DISPLAY DEVICE
911 SPEAKER
912 MICROPHONE
913 INPUT DEVICE
914 BUS
BL BIT LINE
SL SIGNAL LINE
WL WORD LINE

1. A semiconductor device comprising a stack of a first semiconductor substrate and a second semiconductor substrate, wherein
the first semiconductor substrate includes:
an imaging element that generates a charge in response to light from a light incident surface of the first semiconductor substrate; and
a first memory element provided on a side opposite to the light incident surface with respect to the imaging element, and
the first memory element
has a stacked structure in which a magnetization fixed layer, a nonmagnetic layer, and a storage layer are stacked in the order mentioned from the light incident surface side.

2. The semiconductor device according to claim 1, wherein
a cross section of the first memory element cut along a stacking direction has a trapezoidal shape, and
a length of an upper base located on the light incident surface side of the trapezoid is longer than a length of a lower base of the trapezoid.

3. The semiconductor device according to claim 1, wherein the second semiconductor substrate includes a logic circuit.

4. The semiconductor device according to claim 1, wherein the first semiconductor substrate and the second semiconductor substrate are joined to each other by junction electrodes provided to the first semiconductor substrate and the second semiconductor substrate.

5. The semiconductor device according to claim 4, wherein the junction electrodes are formed of copper.

6. The semiconductor device according to claim 1, wherein
the first memory element further includes
a first electrode and a second electrode sandwiching the stacked structure,
the first electrode is located on the light incident surface side with respect to the stacked structure, and
the second electrode is electrically connected with a selection transistor.

7. The semiconductor device according to claim 6, wherein the selection transistor is an n-type MOS transistor.

8. The semiconductor device according to claim 1, wherein
the first memory element is electrically connected to a read transistor and a write transistor, and
film thicknesses of gate oxide films of the read transistor and the write transistor are different from each other.

9. The semiconductor device according to claim 1, wherein the first semiconductor substrate includes:
a pixel region including a plurality of the imaging elements arrayed two-dimensionally; and
a memory area including a plurality of the first memory elements arrayed two-dimensionally.

10. The semiconductor device according to claim 9, wherein at least some of the plurality of first memory elements are volatile storage elements.

11. The semiconductor device according to claim 9, wherein at least some of the plurality of first memory elements are nonvolatile storage elements.

12. The semiconductor device according to claim 9, wherein the plurality of first memory elements includes a volatile storage element and a nonvolatile storage element.

13. The semiconductor device according to claim 11, wherein the nonvolatile storage element includes an OTP storage element in which the nonmagnetic layer is destroyed.

14. The semiconductor device according to claim 9, wherein the memory area includes a logic circuit.

15. The semiconductor device according to claim 1, wherein the second semiconductor substrate does not include a memory element.

16. The semiconductor device according to claim 9, wherein the second semiconductor substrate includes a plurality of second memory elements.

17. The semiconductor device according to claim 16, wherein
each of the second memory elements
has a stacked structure in which a storage layer, a nonmagnetic layer, and a magnetization fixed layer are stacked in the order mentioned from the first semiconductor substrate side.

18. The semiconductor device according to claim 16, wherein each of the first memory elements and each of the second memory elements are connected in series.

19. The semiconductor device according to claim 18, further comprising
a plurality of memory element pairs each including one of the first memory elements and one of the second memory elements connected in series, wherein
individual resistance values of the plurality of memory element pairs are different from each other.

20. An electronic device mounted with a semiconductor device, the semiconductor device including a stack of a first semiconductor substrate and a second semiconductor substrate, wherein
the first semiconductor substrate includes:
an imaging element that generates a charge in response to light from a light incident surface of the first semiconductor substrate; and
a first memory element provided on a side opposite to the light incident surface with respect to the imaging element, and
the first memory element
has a stacked structure in which a magnetization fixed layer, a nonmagnetic layer, and a storage layer are stacked in the order mentioned from the light incident surface side.
